(19) United States
(12) Patent Application Publication
(10) Pub. No.: US 2024/0178844 A1
(43) Pub. Date: May 30, 2024

(54) QUANTUM COMPUTATION DEVICE AND OPERATION THEREOF

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Hsi-Sheng GOAN, Taipei City (TW); Chia-Hsien HUANG, Kaohsiung City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/366,577

(22) Filed: Aug. 7, 2023

Related U.S. Application Data
(60) Provisional application No. 63/411,098, filed on Sep. 28, 2022.

(51) Int. Cl. H03K 19/195; G06N 10/40; H01L 29/775

(52) U.S. Cl. CPC H03K 19/195; G06N 10/40; H01L 29/775

(57) ABSTRACT

A method is provided, including: applying a magnetic field according to a two-qubit gate operation performed with a quantum device; transmitting a voltage signal to a gate structure, arranged above first and second quantum dots in the quantum device, to generate a coupling signal that includes a first sine squared wave; and performing, by the magnetic field and the coupling signal, the two-qubit gate operation to the first and second qubits in the first and second quantum dots.

### CROSS-REFERENCE TO RELATED APPLICATION

The present application claims priority to U.S. Provisional Patent Application No. 63/411,098, filed on Sep. 28, 2022, which is incorporated by reference herein in its entirety.

### BACKGROUND

In quantum computing, a quantum gate is a basic circuit operating on a number of qubits. The most common quantum gates include two-qubit quantum gates, which operate on vector spaces of two qubits. For a two-qubit quantum gate, its fidelity is limited by noises, cross-talk errors, and so on. The fidelity for two-qubit gates implemented by current experimental methods is not great enough, causing errors when the gates are used for quantum computing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is schematic diagram illustrating a quantum system, in accordance with some embodiments of the present disclosure.

FIG. 2 is a schematic diagram showing example qubit operations of a quantum logic circuit corresponding to the quantum device of FIG. 1, in accordance with some embodiments of the present disclosure.

FIG. 3 is a cross-section view of part of a quantum device corresponding to the quantum device in FIG. 1, in accordance with some embodiments of the present disclosure.

FIG. 4 is a top view of a portion of the quantum device corresponding to the quantum devices in FIGS. 1 and 3, in accordance with some embodiments of the present disclosure.

FIG. 5 is a cross-section view of a portion of the quantum device of FIG. 4 along a line Y1-Y2, in accordance with some embodiments of the present disclosure.

FIG. 6 is a schematic circuit diagram including a top view of a portion of a quantum device corresponding to the quantum devices in FIGS. 1 and 3, in accordance with some embodiments of the present disclosure.

FIG. 7 is a cross-section view of a portion of the quantum device of FIG. 6 along a line Y3-Y4, in accordance with some embodiments of the present disclosure.

FIG. 8A is a waveform diagram for a magnetic field corresponding to that shown in FIGS. 4 and 6, in accordance with some embodiments of the present disclosure.

FIG. 8B is a waveform diagram for a coupling signal corresponding to that shown in FIGS. 5 and 7, in accordance with some embodiments of the present disclosure.

FIG. 9 is a waveform diagram for a coupling signal corresponding to that shown in FIGS. 5 and 7, in accordance with various embodiments of the present disclosure.

FIG. 10 is a waveform diagram for a coupling signal corresponding to that shown in FIGS. 5 and 7, in accordance with various embodiments of the present disclosure.

FIG. 11 is a schematic diagram showing example qubit operations of a quantum logic circuit corresponding to that in FIG. 2, in accordance with some embodiments of the present disclosure.

FIG. 12 is a waveform diagram for a coupling signal and a magnetic field corresponding to those shown in FIGS. 4-7, in accordance with various embodiments of the present disclosure.

FIG. 13A is a waveform diagram for a portion of a magnetic field corresponding to that shown in FIGS. 4 and 6, in accordance with some embodiments of the present disclosure.

FIG. 13B is a waveform diagram for a portion of a magnetic field corresponding to that shown in FIGS. 4 and 6, in accordance with some embodiments of the present disclosure.

FIG. 13C is a waveform diagram for a coupling signal corresponding to that shown in FIGS. 5 and 7, in accordance with some embodiments of the present disclosure.

FIG. 14 is a schematic diagram showing example qubit operations of a quantum logic circuit corresponding to that in FIG. 2, in accordance with some embodiments of the present disclosure.

FIG. 15 is a schematic diagram showing example qubit operations of a quantum logic circuit corresponding to that in FIG. 2, in accordance with some embodiments of the present disclosure.

FIG. 16 is a schematic diagram showing example qubit operations of a quantum logic circuit corresponding to that in FIG. 2, in accordance with some embodiments of the present disclosure.

FIG. 17 is a schematic diagram showing example qubit operations of a quantum logic circuit corresponding to that in FIG. 2, in accordance with some embodiments of the present disclosure.

FIG. 18 is a schematic diagram showing example qubit operations of a quantum logic circuit corresponding to that in FIG. 2, in accordance with some embodiments of the present disclosure.

FIG. 19 is a flowchart of a method for quantum computation, in accordance with some embodiments of the present disclosure.

FIG. 20 is a flowchart of a method for quantum computation, in accordance with some embodiments of the present disclosure.

FIG. 21 is a flowchart of a method for quantum computation, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

As used herein, the terms “comprising,” “including,” “having,” “containing,” “involving,” and the like are to be understood to be open-ended, i.e., to mean including but not limited to.

Reference throughout the specification to “one embodiment,” “an embodiment,” or “some embodiments” means that a particular feature, structure, implementation, or characteristic described in connection with the embodiment(s) is included in at least one embodiment of the present disclosure. Thus, uses of the phrases “in one embodiment” or “in an embodiment” or “in some embodiments” in various places throughout the specification are not necessarily all referring to the same embodiment. Furthermore, the particular features, structures, implementation, or characteristics may be combined in any suitable manner in one or more embodiments.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, the term “and/or” includes any and all combinations of one or more of the associated listed items.

In certain realizations, the quantum computing system demonstrates its prowess in quantum computation through the storage and manipulation of information within individual quantum states of a composite quantum system. An illustrative example involves the utilization of qubits, which are quantum bits, and their representation as a two-level sub-manifold within a coherent physical system. In some embodiments, the term “qubits” refers both to these physical systems retaining the information and to the qubits themselves that form the fundamental elements of quantum computing. Comparable to classical computer bits, qubits can exist in a quantum state of |0> or |1>, or they can exhibit a superposition of both states, such as a combination of |0> and |1>. However, upon measurement, qubits always yield either |0> or |1> based on their initial quantum state. To accomplish quantum computing with composite systems, it is possible to establish connections between individual physical qubits, enabling conditional quantum logic operations. In some cases, these connections can be formed in a way that facilitates extensive entanglement within the quantum computing device. Control signals come into play to perform quantum operation in order to manipulate the quantum states of individual qubits and the connections between them. Furthermore, the information stored in the composite quantum system can be retrieved by measuring the quantum states of the individual qubits. In some embodiments, the retrieved information are feedback to classical circuits for circuit operation.

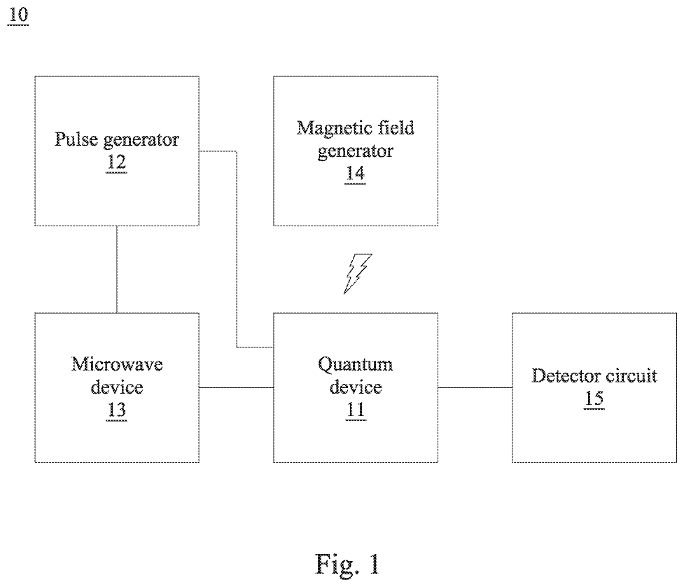

Reference is now made to FIG. 1. FIG. 1 is schematic diagram illustrating a quantum system 10, in accordance with some embodiments of the present disclosure. For illustration, the quantum system 10 includes a quantum device 11, a pulse generator 12, a microwave device 13, a magnetic field generator 14, and a detector circuit 15. In some embodiments, the pulse generator 12, the microwave device 13, and the detector circuit 15 are electrically connected to the quantum device 11, and the magnetic field generator 14 provides magnetic field for quantum operation of the quantum device 11.

In some embodiments, the quantum device 11 includes quantum interaction gates, circuits, cores that have numerous of quantum structures/cells consisted of, for example, qubits, quantum dots, etc., and control lines transmitting control signals configured to control the quantum structures with, for example, coupling and energy levels of qubits, in operation.

The pulse generator 12 and the microwave device 13 are configured to generate the control signals configured to control quantum logic operations, readout operations or other types of operations of the quantum device 11. For example, the pulse generator 12 generates the analog control signals and controls amplitude of the control signals according to the digital control information of quantum operations to the quantum device 11 and/or the microwave device 13. The microwave device 13 modulates the control signals to oscillate at selected frequencies and outputs the control signals to perform a qubit or multi-qubit operation in the quantum device 11. In the quantum operation, the magnetic field generator 14 provides a direct current (DC) magnetic field to the quantum device 11 in order to minimize spin-orbit coupling and to reduce the qubit' sensitivity to charge noise. After the operation, the detector circuit 15 then converts the quantum states, manipulated by the operation, of qubits in the quantum device 11 into a classic circuit signals be processed, for example, by a classical processor running software or dedicated classical processing hardware.

In some embodiments, the pulse generator 12 includes, for example, an arbitrary waveform generator (AWG), a vector network analyzer (VNA), and/or other suitable pulse generator device. The microwave device 13 includes, for example, a vector microwave source or other suitable microwave generator. The magnetic field generator 14 includes, for example, microwave transmission line(s) or one or more magnets or other suitable magnetic field generator providing the DC magnetic field to the quantum device 11. The detector circuit 15 includes transimpedance amplifier, voltage amplifier, filters, an oscilloscope, or the combinations thereof.

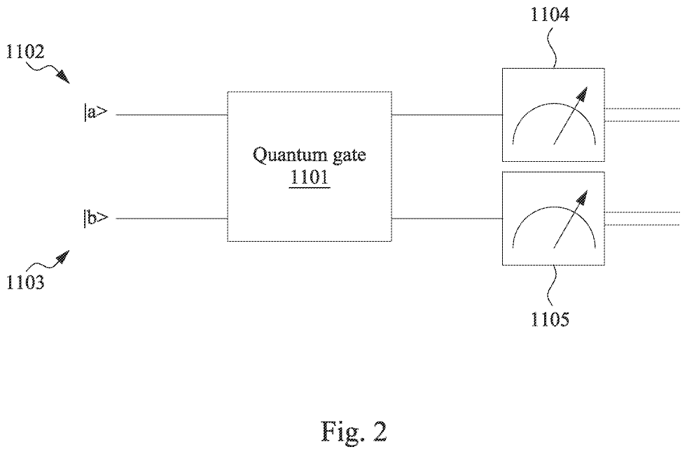

Reference is now made to FIG. 2. FIG. 2 is a schematic diagram showing example qubit operations of a quantum logic circuit corresponding to the quantum device of FIG. 1, in accordance with some embodiments of the present disclosure. In some embodiments, FIG. 2 is referred to as a quantum gate circuit diagram.

In some embodiments, the quantum device 11 includes structures performing an operation of a quantum gate 1101 in response to the control signals generated by the pulse generator 12 and the microwave device 13 and the magnetic field from the magnetic field generator 14. Initially, in a two-qubit mechanic system of the quantum device 11 a qubit 1102 is in a state |a> and a qubit 1103 is in a state |b>. Each of the states |a> and |b> is one of the computational basis states |0>, |1>, and a superposition of the |0> and |1> states. A quantum operation of the quantum gate 1101 is then applied to the qubits 1102 and 1103, modulating the quantum states of the qubits 1102 and 1103.

The qubits 1102 and 1103 are then measured respectively by measurement operations 1104 and 1105 that are performed in response to control signals from the pulse generator 12 according to some embodiments. The measurement operation 1104 collapses the qubit 1102 to one of its computational basis states, either |0> or |1>, and produces a corresponding binary measurement result. The measurement operation 1105 collapses the qubit 1103 to one of its computational basis states, either |0> or |1>, and produces a corresponding binary measurement result. The detector circuit 15 outputs the binary measurement results corresponding to the qubits 1102 and 1103 as output information of the quantum device 11.

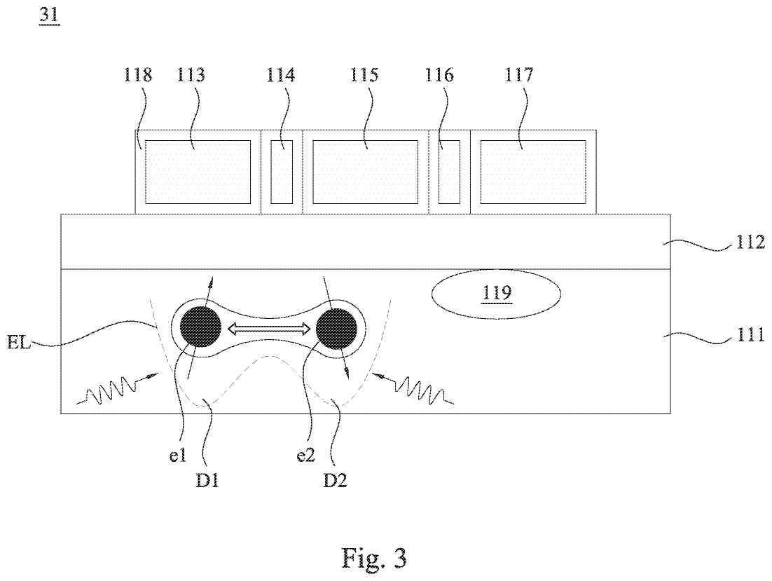

In some embodiments, the qubits in the quantum device are encoded directly on the spins of individual nuclei, donor-bound electrons, or electrons confined in gate-defined quantum dots or in subspaces provided by two or more spins. Electrostatic electrodes allow initialization, readout and manipulation of qubits to be implemented with electrical control signals and magnetic fields. Exemplary embodiments are provided in FIG. 3.

Reference is now made to FIG. 3. FIG. 3 is a cross-section view of part of a quantum device 31 corresponding to the quantum device 11 in FIG. 1, in accordance with some embodiments of the present disclosure. In some embodiments, the quantum device 31 is configured with respect to, for example, the quantum device 11 of FIG. 1. As shown in FIG. 3, a high-level schematic diagram illustrates that the quantum device 31 includes a substrate 111, a semiconductor layer 112, conductive structures 113-117 in an oxide layer 118 arranged above the semiconductor layer 112, and a reservoir region 119 that is in the substrate 111 and underneath the conductive structure 117. The oxide layer 118 isolates the conductive structures from each other.

For illustration, quantum dots D1 and D2 are formed in the substrate 111 and under the conductive structures 113 and 115. In some embodiments, the quantum dots D1-D2 are nanostructures in the substrate 111 that confines electrons to a small area. A line EL indicates energy barrier of the quantum dots D1 and D2.

In some embodiments, the conductive structure 117 is configured as a reservoir gate structure to accumulate the reservoir region 119 for loading and unloading electrons e1-e2 to the quantum dots D1-D2 through a channel region between the reservoir region 119 and the quantum dots D1-D2 in response to a control signal received by the conductive structure 117 and an electrical field provided by a control signal applied on the conductive structure 116. Alternatively stated, the tunneling of the electrons e1-e2 between the quantum dots D1-D2 depends on the voltage level of the control signal to the conductive structure 116.

For the quantum operation, the electrons e1 an e2 from the reservoir region 119 are transmitted and loaded into the quantum dots D1 and D2 in sequence responsive to control signals applied on the conductive structures 116-117, which initializes qubits q1-q2. A quantum operation is then performed on the qubits q1-q2 by inducing an exchange coupling J in response to at least a control signal applied on the conductive structure 114 and magnetic fields to change the spins of the electrons e1 and e2, and accordingly the quantum states, encoded by the spins of the electrons e1-e2, of the qubits q1-q2 are manipulated. Furthermore, the qubits q1 and q2 are read out in sequence via spin-dependent tunneling to the reservoir region 119, which concludes the operational sequence.

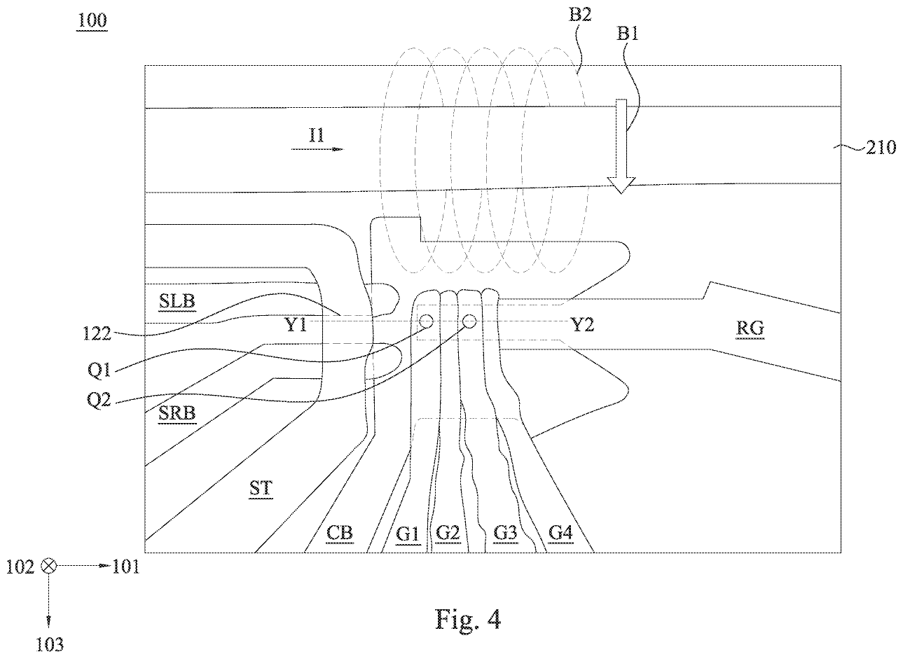

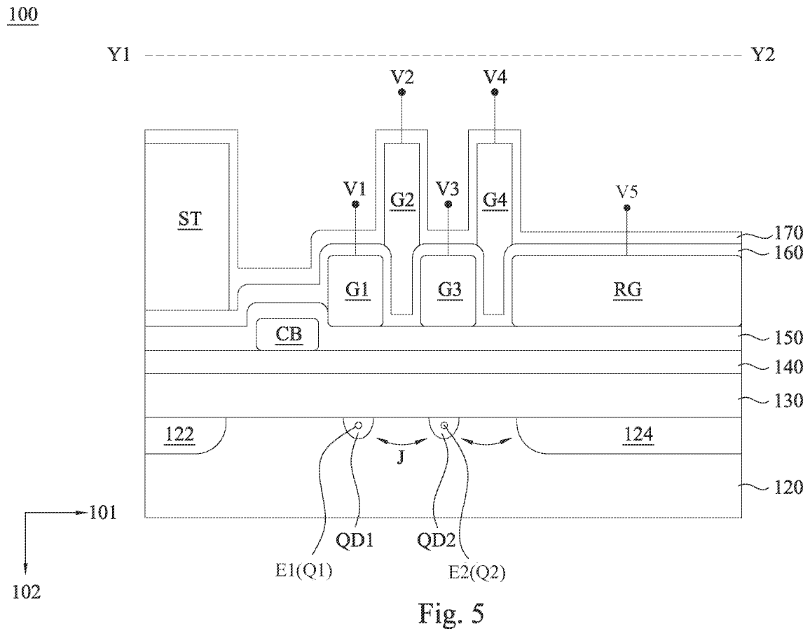

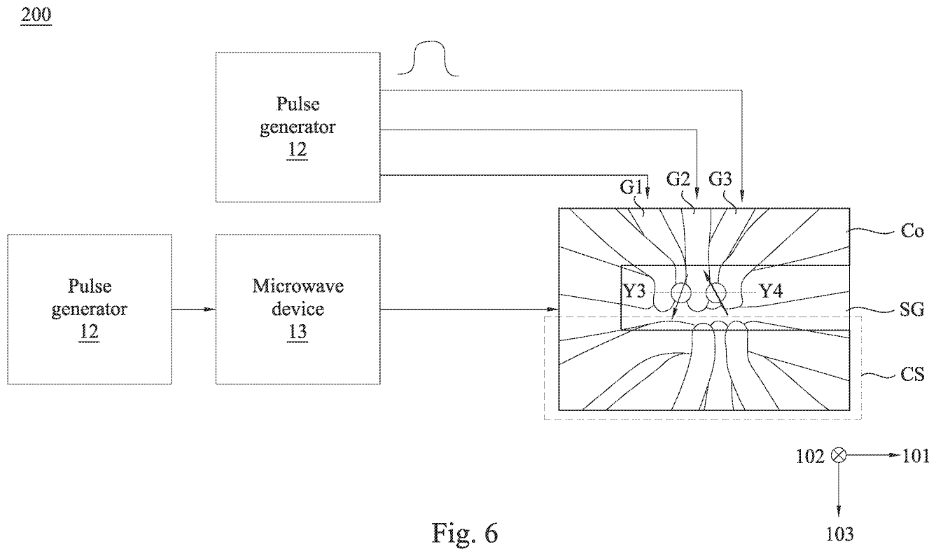

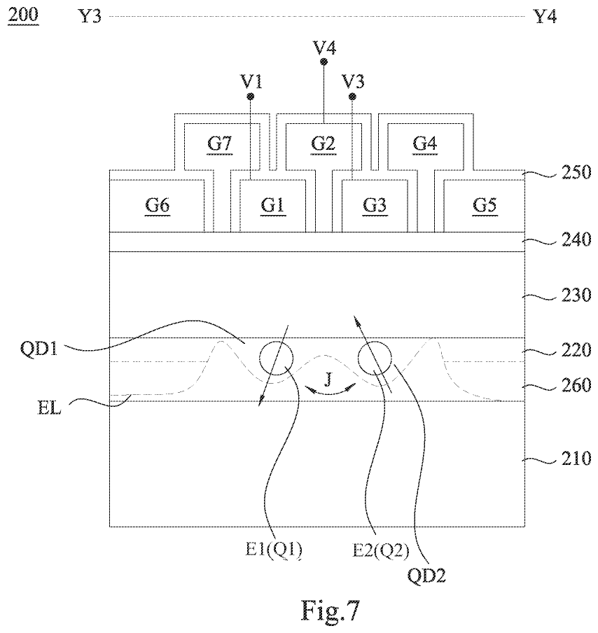

Based on the discussion above, by engineering the electrical fields and local magnetic field gradients, electron spins can be controlled by two-qubit gates with high fidelity. In some embodiments, the coupling signal J and the magnetic field are referred to as control signals to the quantum devices 100 and 200 in quantum operations. Two operational schemes are discussed with reference to a quantum device 100, utilizing the electron spin resonance (ESR) method, of FIGS. 4-5 and another quantum device 200, utilizing the electric-dipole spin resonance (EDSR) method, of FIGS. 6-7 separately.

Reference is now made to FIGS. 4-5. FIG. 4 is a top view of a portion of the quantum device corresponding to the quantum device in FIGS. 1 and 3, and FIG. 5 is a cross-section view of a portion of the quantum device of FIG. 4 along a line Y1-Y2, in accordance with some embodiments of the present disclosure. In some embodiments, the quantum device 100 is configured with respect to the quantum device 31 of FIG. 3 and referred to as a silicon metal-oxide-semiconductor field-effect transistor (Si-MOSFET) quantum-dot electron-spin-qubit device.

As illustrative shown in FIG. 5, the quantum device 100 includes a substrate 120, an electron reservoir 124, quantum dots QD1-QD2, layers 130-170, gate structures G1-G4, and a reservoir gate structure RG. In some embodiments, the substrate 120 is configured with respect to the substrate 111 of FIG. 3. The layers 130-150 are configured with respect to the semiconductor layer 112 of FIG. 3. The layers 160-170 are configured with respect to the oxide layer 118 of FIG. 3. The gates G1-G4 and RG are configured with respect to the conductive structures 113-117 of FIG. 3 separately. The electron reservoir 124 is configured with respect to the reservoir region 119 of FIG. 3. The quantum dots QD1-QD2 are configured with respect to the quantum dots D1-D2 of FIG. 3.

Compared with the quantum device 31 of FIG. 3, the quantum device 100 further includes a confinement gate structure CB, a gate structure ST, and an island 122 formed below the gate structure ST. In some embodiments, the confinement gate structure CB is configured to receive a control signal and to confine the quantum dots QD1-QD2 in response to the control signal. During the quantum operations, the electric field provided by the confinement gate structure CB builds an energy barrier to keep the electrons E1 and E2 in the quantum dots QD1-QD2. The gate structure ST and the island 122 are included in a charge sensor configured to read out the quantum states of qubits Q1-Q2 after the quantum operations. The detailed operations will be discussed later.

In FIG. 5, for illustration, the layer 130 is arranged on the substrate 120. The layer 140 is arranged on the layer 130. The confinement gate structure CB is arranged on the layer 140. The layer 150 is arranged on the layer 140 and the confinement gate structure CB. The gate structures G1 and G3 and the reservoir gate structure RG are arranged on the layer 150. The layer 160 is arranged on the layer 150, the gate structures G1 and G3, and the reservoir gate structure RG. The gate structure ST and the gate structures G2 and G4 are arranged on the layer 160. The layer 170 is arranged on the layer 160, the gate structure ST, and the gate structures G2 and G4. For illustration of FIG. 4, along the line Y1-Y2, the gate structure ST of the charge sensor, the confinement gate structure CB, the gate structures G1-G4, and the reservoir gate structure RG are sequentially arranged along the direction 101 from the top view. Specifically, the gate structures G1-G4 extend in direction 103 and shrink between the confinement gate structure CB and the reservoir gate structure RG. The reservoir gate structure RG extends in the direction 101. The confinement gate structure CB, surrounding portions of the gate structures G1-G4, is arranged between the island 122 and the reservoir gate RG in the top view of the quantum device 100. A portion of the confinement gate structure CB is arranged below the gate structures G1-G4 and the reservoir gate RG, as indicated by the dashed lines in the middle of FIG. 4. Other structures of the quantum device 100 will be discussed with operation in the following paragraphs.

In some embodiments, the gate structures G1-G4 are configured to receive voltage signals V1-V4 as control signals from the pulse generator 12 for initializing the qubits Q1-Q2, performing quantum gate operations, and reading out the qubits Q1-Q2.

In operation, for firstly initializing the qubit Q1 the voltage signal V4 is applied on the gate structure G4 to turn on a channel between the electron reservoir 124 and the quantum dot QD2 to transmit the electron E1 from the electron reservoir 124 to the quantum dot QD2. In some embodiments, a voltage signal V5 applied on the gate structure RG expels electrons from the electron reservoir 124. When the gate structure G1 receives the voltage signal V1 with a positive voltage level and the gate structure G2 receives the voltage signal V2 with a negative voltage level, the electron E1 in the quantum dot QD2 is drawn toward the gate structure G1 through a channel between the quantum dots QD1-QD2. The electron E1 is then confined in the quantum dot QD1 below the gate structure G1 and the qubit Q1 encoded by a spin of the electron E1 in the quantum dot QD1 is initialized accordingly.

For initializing the qubit Q2, another electron E2 is transmitted to the quantum dot QD2 from the electron reservoir 124 through the turned on channel between the electron reservoir 124 and the quantum dot QD2 in response to the gate structure G3 receiving the voltage signal V3 with a positive voltage level and the gate structures G2 and G4 receiving the voltage signs V2 and V4 with negative voltage levels. The electron E2 is then confined in the quantum dot QD2 below the gate structure G3 and the qubit Q2 encoded by a spin of the electron E2 in the quantum dot QD2 is initialized accordingly.

In various embodiments, the substrate 120 is filled with electric holes, and when the voltage signals V1 and V3 have negative voltage signals, those electric holes will be drawn toward the gate structures G1 and G3 and form the quantum dots QD1-QD2.

After the initialization of the qubits Q1-Q2, the pulse generator 12 is further configured to adjust, according to the type of the quantum gate operation (e.g., a controlled-Z(CZ) gate operation, a controlled-NOT(CNOT) gate operation, etc.,) the voltage signals V1-V3 transmitted to the gate structures G1-G3 to generate a coupling signal J between the quantum dots QD1-QD2, in which the coupling signal J is associated with the detuning and tunneling between the quantum dots QD1-QD2.

Specifically, for preforming quantum gate operation, the pulse generator 12 adjusts the voltage signals V1 and V3 applied to the gate structures G1 and G3 to have the detuning energy between the quantum dots QD1-QD2 large enough against the on-site Coulomb energy of the electrons E1-E2 in the quantum dots QD1-QD2. Furthermore, the pulse generator 12 controls the voltage signal V2 applied to the gate structure G2 to have a high voltage level to provide sufficient tunneling energy for inducing tunneling of electrons E1-E2 between the quantum dots QD1-QD2, and accordingly, the strong coupling signal J is generated for manipulating the states of the quantum bits in the quantum gate operations.

In some embodiments, the coupling signal J is represented as the equation (1) below:

$$J ≅ \frac{{t}_{0}^{2}}{{U}_{1} - ε} + \frac{{t}_{0}^{2}}{{U}_{2} + ε} \\ {E}_{tunneling} = \frac{{t}_{0}}{ℏ} , {E}_{detuning} = \frac{ε}{ℏ} , {E}_{{Coulomb}_{QD 1}} = \frac{{U}_{1}}{ℏ} , {E}_{{Coulomb}_{QD 2}} = \frac{{U}_{2}}{ℏ} \qquad ( 1 )$$

E_{tunneling} refers to as the interdot tunneling energy of the quantum dots QD1-QD2. E_{detuning} refers to as the detuning energy of the quantum dots QD1-QD2, or relative alignment of the potential of the quantum dots QD1-QD2. E_{Coulomb}_{_{QD1}} refers to as the on-site Coulomb energy of the quantum dot QD1. E_{Coulomb}_{_{QD2}} refers to as the on-site Coulomb energy of the quantum dot QD2.

$$ℏ ≡ \frac{h}{2 π} ,$$

and h is the Planck constant.

As the formula above indicates, the coupling signal J is associated with t₀ and/or ϵ in which t₀ is related to the voltage signal V2 applied to the gate structure G2, and ϵ is related to the difference between the voltage signals V1 and V3. In some embodiments, t₀ is, in a certain range, proportional to the voltage signal V2, and ε is, in a certain range, proportional to the difference between the voltage signals V1 and V3.

In some embodiments, the transformation relation between the voltage signals V1-V3 and the coupling signal J is obtained from the experimental calibration. In some embodiments, when the voltage signals V1-V3 are provided to the gate structures G1-G3, the energy levels of the qubits in the quantum dots QD1-QD2 shift correspondingly and the coupling signal J therebetween is obtained based on the shift of the energy levels. Based on the measured coupling signal J, the voltage signals V1-V3 are adjusted or calibrated in order to generate optimized coupling signal J. Alternatively stated, through the process of calibration, the coupling signal J is accurately controlled by the voltage signals V1-V3 based on the transformation relation therebetween.

In addition to the coupling signal J generated for the quantum operation, the pulse generator 12 and the microwave device 13 also transmit control signals to generate alternating current (AC) portion of the magnetic field, for example, B2 of FIG. 4, to the quantum device 100 for the quantum gate operation. In some embodiments, by controlling the coupling signal J and the magnetic field including the direct current portion B1 and/or the alternating current portion B2, a quantum gate operation is performed on the qubits Q1-Q2.

Specifically, in FIG. 4, two portions B1-B2 of the magnetic field applied to the qubits Q1-Q2 for the quantum gate operations are illustrated. The portion B1 is provided to minimize spin-orbit coupling and to reduce the qubits' sensitivity to charge noise. In some embodiments, the direct-current (DC) portion B1 of the magnetic field has a fixed direction along an in-plane direction 103. In some embodiments, the portion B1 has a constant value and does not vary with respect to time. In some embodiments, the portion B1 is an external magnetic field generated by the magnetic field generator 14 of FIG. 1.

The portion B2 of the magnetic field is an alternating-current (AC) magnetic field generated by a microwave pulse current I1 transmitted to an electric line 201, as shown in FIG. 5. The oscillating portion B2 of the magnetic field manipulates the electron spins and the qubit state rotations of the qubits Q1-Q2, employing the electron spin resonance (ESR) method. In some embodiments, the lines of magnetic flux will form concentric circles around the electric line 201, and the magnetic field B2 applied to the qubits Q1-Q2 are along the direction 102 or opposite to the direction 102. In some embodiments, the pulse generator 12 provides a modulation control signal to microwave device 13 to generate the microwave pulse current I1. The microwave pulse current I1 flows through the electric line 201, referred to as an ESR line or a microwave antenna, generates the portion B2 of the magnetic field.

In some embodiments, the portion B2 of the magnetic field is represented as the equation (2) below:

$$B 2 = {Ω}_{X} ( t ) cos ( 2 π ft ) {Ω}_{Y} ( t ) cos ( 2 π ft + \frac{π}{2} ) \qquad ( 2 )$$

Ω_{X}(t) is referred to as an in-phase amplitude, Ω_{Y}(t) is referred to as a quadrature amplitude, and f is a driving frequency of the portion B2 of the magnetic field.

In some embodiments, a single driving frequency is used to drive the qubits Q1-Q2 to be on-resonance or off-resonance. In various embodiments, two driving frequencies are used to drive the qubits Q1-Q2 to be on-resonance or off-resonance respectively.

With reference to FIGS. 4-5, after the qubits Q1-Q2 are manipulated by the quantum gate operation induced by the coupling pulse J and the magnetic field, In measurement operation the charge sensor as discussed above, including the gate structure ST, the island 122 and gate structures SLB, SRB in FIG. 4, is configured to sense, in response to control signals from the pulse generator 12, the electrons movement among the quantum dots QD1-QD2 for reading out the quantum states of the qubits Q1-Q2. As illustratively shown in FIG. 4, the island 122 is formed between the gate structures SLB, SRB and underneath the gate structure ST.

The charge sensor as discussed above is also referred to as a single-electron transistor (SET). The gate structure ST corresponds to a gate terminal and the gate structures SLB and SRB correspond to drain and source terminals of the SET. In operation, by controlling the voltage levels of the gate structures ST, G1-G4, the confinement gate structure CB and the reservoir gate RG, the spin readout operation of electrons E1-E2 corresponding to the qubits Q1-Q2 is performed in a single-shot measurement via spin-dependent tunneling to generate a current that flows through the gate structures SLB and SRB and indicates the quantum states of the qubits Q1-Q2. For example, with reference to FIGS. 4-5, the current has a first value when the electron that has a spin-up state and corresponds to one of the qubits Q1-Q2 moves to the electron reservoir 124 through tunneling, and the current has a second value when the electron that has a spin-down state and corresponds to one of the qubits Q1-Q2 keeps in the corresponding quantum dot due to lack of sufficient tunneling energy to the electron reservoir 124. Accordingly, the quantum states of the qubits Q1-Q2 are measured and the detector circuit 15 of FIG. 1 converts the current into binary signal for other circuit application in some embodiments.

In some embodiments, the substrate 120 is a silicon epitaxy layer and includes material layer(s) that includes, for example, silicon or silicon germanium (SiGe). The layer 130 includes silicon oxide. The layers 140, 150, 160, and/or 170 include aluminum oxide. The above materials of the substrate 120 and the layers 130-170 are given for illustrative purposes. Various materials of the substrate 120 and the layers 130-170 are within the contemplated scope of the present disclosure.

In some embodiments, the layers 140-170 are configured to isolate the charge sensor formed by the gate structures ST. SLB, and SRB, the confinement gate structure CB, the gate structures G1-G4, and the reservoir gate structure RG from each other and prevent them from contacting and shorting with each other.

In some embodiments, the charge sensor formed by the gate structures ST. SLB, and SRB, the confinement gate structure CB, the gate structures G1-G4, and/or the reservoir gate structure RG includes one or more layers of conductive/semiconductor material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. In some embodiments, the formation of the charge sensor formed by the gate structures ST. SLB, and SRB, the confinement gate structure CB, the gate structures G1-G4, and/or the reservoir gate structure RG includes, for example, chemical vapor deposition (CVD), atomic layer deposition (ALD), electro-plating, or other suitable method.

In some embodiments, each of the charge sensor formed by the gate structures ST, SLB, and SRB, the confinement gate structure CB, the gate structures G1-G4, and/or the reservoir gate structure RG includes an interfacial layer (not shown) and a polysilicon (or poly) layer (not shown) over the interfacial layer. In some embodiments, the interfacial layer is configured to prevent gate leakage current that induce undesired noise to the quantum operations. In some embodiments, each of the charge sensor formed by the gate structures ST, SLB, and SRB, the confinement gate structure CB, the gate structures G1-G4, and/or the reservoir gate structure RG further includes a gate dielectric layer (not shown) and a metal gate layer (not shown) disposed between the interfacial layer and the poly layer. In some embodiments, the interfacial layer includes a dielectric material including, for example, silicon oxide (SiO2) or silicon oxynitride (SiON). In some embodiments, the gate dielectric layer uses a high-k dielectric material including, for example, hafnium oxide (HfO2), Al2O3, lanthanide oxides, TiO2, HfZrO, Ta2O3, HfSiO4, ZrO2, ZrSiO2, combinations thereof, or other suitable material.

In some embodiments, the quantum device 100 further includes additional gate structures (not shown in FIGS. 4-5) arranged adjacent to the gate structure G4. Such additional gate structures are configured to receive voltage signals to form addition quantum dots or to generate an energy barrier between the quantum dot and the electron reservoir 124.

Reference is now made to FIGS. 6-7 to discuss the quantum device 200 utilizing the electric-dipole spin resonance (EDSR) method. FIG. 6 is a top view of a portion of the quantum device 200 corresponding to the quantum devices in FIGS. 1 and 3, and FIG. 7 is a cross-section view of a portion of the quantum device 200 of FIG. 6 along a line Y3-Y4, in accordance with some embodiments of the present disclosure. With respect to the embodiments of FIGS. 1-5, like elements in FIGS. 6-7 are designated with the same reference numbers for ease of understanding. The specific operations of similar elements, which are already discussed in detail in above paragraphs, are omitted herein for the sake of brevity.

Compared with the quantum device 100 including the quantum dots QD1-QD2 in the silicon epitaxy layer substrate 120, the silicon oxide layer 130 and the aluminum oxide layers 140-150 in the embodiments of FIGS. 4-5, the quantum device 200 in FIGS. 6-7 includes a substrate 210 consisted of a silicon germanium (SiGe) layer and layers 220-240 that are disposed above the substrate 210. In some embodiments, the layers 220 and 240 include silicon layers, and the layer 230 includes a silicon germanium layer. The oxide layer 250 includes an aluminum oxide layer disposed on the gate structures G1-G7 for electrically isolation.

In some embodiments, the substrate 210 and the layer 220 are configured with respect to the substrate 111 of FIG. 3. The layers 230-240 are configured with respect to the semiconductor layer 112 of FIG. 3. The layer 250 is configured with respect to the oxide layer 118 of FIG. 3. The gates G1-G4 and G5 are configured with respect to the conductive structures 113-117 of FIG. 3 separately. An electron reservoir 260 is configured with respect to the reservoir region 119 of FIG. 3.

In operation, after loading the electrons E1-E2 and the initialization of the qubits Q1-Q2 corresponding to the electrons E1-E2, the quantum operations is performed on the qubits Q1-Q2 according to the coupling pulse J in response to the control signals V1-V3 received by the gate structures V1-V3 as discussed with reference to FIGS. 4-5. The repetitious descriptions are omitted there.

With reference to FIG. 6, the aforementioned portion B2 of the magnetic field is generated through the electric-dipole spin resonance (EDSR) method for quantum operations. In the EDSR method, a micro-magnet Co is arranged above the quantum device 200 and is configured to generate an inhomogeneous magnetic field across the quantum dots QD1-QD2 along the direction 101. Moreover, the pulse generator 12 is configured to transmit a control signal to the microwave device 13 for generating a microwave pulse to a gate structure SG. A microwave electric field applied to the quantum dots QD1-QD2 is induced in response to the microwave pulse transmitted in the gate structure SG. The microwave electric field displaces the electrons E1-E2 back and forth in the inhomogeneous magnetic field and generates the oscillating portion B2 of the magnetic field in the electron's rest frame.

In addition, a charge sensor configured as the one discussed with reference to FIGS. 4-5 is arranged net to the gate structure SG to generate a current indicating the quantum states of the qubits Q1-Q2.

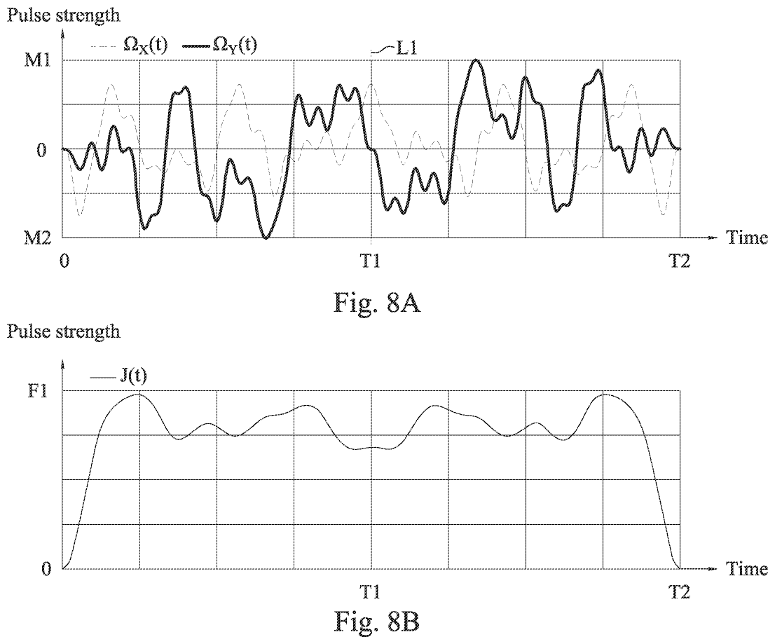

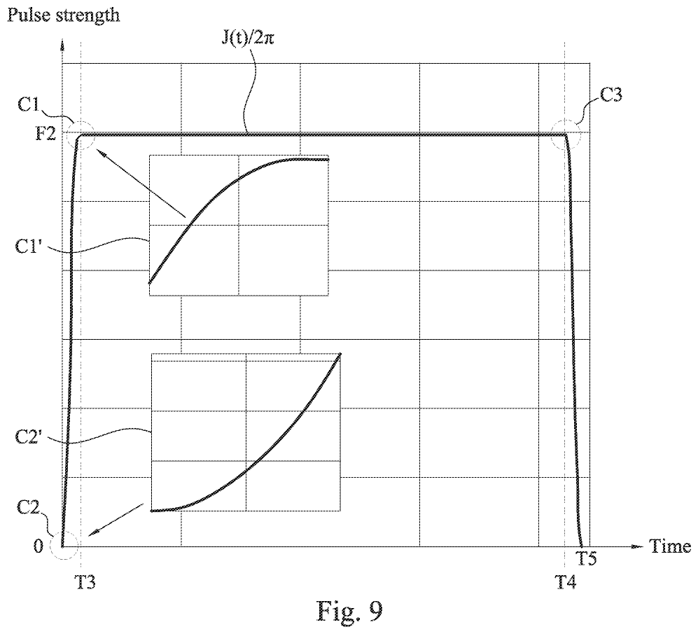

In some embodiments, by controlling the coupling signal J and the portion B1 and/or the portion B2 of the magnetic field that are applied to the quantum device 100 or the quantum device 200, a desired quantum gate can be operated on the qubits Q1-Q2. For example, the quantum gate operation includes, for example, controlled-Z (CZ) gate operation, controlled-NOT (CNOT) gate operation, and so on. In the following paragraphs, the embodiments of the controlled-NOT (CNOT) gate operation are given with reference to FIGS. 8A-8B and FIGS. 11-13C, and the embodiments of the controlled-Z (CZ) gate operations are given with reference to FIGS. 9-10.

The CNOT gate operates on a quantum register consisting of 2 qubits. The CNOT gate operation flips the second qubit (the TARGET qubit) if and only if the first qubit (the CONTROL qubit) is |1>. When {|0>,|1>} are the only allowed input values for both qubits, then the TARGET output of the CNOT gate operation corresponds to the result of a classical XOR gate. Fixing CONTROL as |1>, the TARGET output of the CNOT gate operation yields the result of a classical NOT gate. More generally, the inputs are allowed to be a linear superposition of {|0>,|1>}. The CNOT gate operation transforms the quantum state a|00>+b|01>+c|10>+d|11> into a|00>+b|01>+c|11>+d|10>. The truth table of the CNOT gate operation is provided as below:

| | |
|---|---|
| INPUT | OUTPUT |

| CONTROL | TARGET | CONTROL | TARGET |
|---|---|---|---|
| (1^{st} qubit) | (2^{nd} qubit) | (1^{st} qubit) | (2^{nd} qubit) |
| \|0> | \|0> | \|0> | \|0> |
| \|0> | \|1> | \|0> | \|1> |
| \|1> | \|0> | \|1> | \|1> |
| \|1> | \|1> | \|1> | \|0> |

The controlled-Z (CZ) gate operation consists of 2 qubits and applies a Z-gate (inverting phase) to the TARGET qubit if the CONTROL qubit is |1>. Specifically, The CZ gate operation is equivalent to the exact CZ gate operation up to some single-qubit Z rotations. The single-qubit Z rotations are absorbed into the phases of the subsequent single-qubit X or Y rotations. In some embodiments, the single-qubit Z rotations are performed by instantaneous phase switching on the microwave source that generates the AC magnetic fields for the X or Y rotations. The single-qubit Z rotations in this case do not include any physical pulses, do not generate extra errors, and are regarded as virtual gates. The truth table of the CZ gate operation is provided as below:

| | |
|---|---|
| INPUT | OUTPUT |

| CONTROL | TARGET | CONTROL | TARGET |
|---|---|---|---|
| (1^{st} qubit) | (2^{nd} qubit) | (1^{st} qubit) | (2^{nd} qubit) |
| \|0> | \|0> | \|0> | \|0> |
| \|0> | \|1> | \|0> | \|1> |
| \|1> | \|0> | \|1> | \|0> |
| \|1> | \|1> | \|1> | −\|1> |

Reference is now made to FIGS. 8A-8B. FIG. 8A is a waveform diagram for the portion B2 of the magnetic field corresponding to FIGS. 4 and 6, in accordance with some embodiments of the present disclosure. FIG. 8B is a waveform diagram for the coupling signal J as shown in FIGS. 5 and 7, in accordance with some embodiments of the present disclosure.

The CNOT gate operation is performed by the constant portion B1 of the magnetic field, the portion B2 of the magnetic field with Ω_{X}(t) and Ω_{Y}(t) and the coupling signal J with J(t) as shown in FIGS. 8A-8B. Because Ω_{X}(t), Ω_{Y}(t), and J(t) are all activated between time=0 and a time T2, the CNOT gate operation is referred to as a single-shot CNOT gate operation. The time T2 is referred to as an operation time of the CNOT gate operation. A time T1 is a middle time point of the operation time of the CNOT gate operation (time T2).

As shown by the equation (2) discussed above, the portion B2 of the magnetic field includes a portion corresponding to Ω_{X}(t) and a portion corresponding to Ω_{Y}(t). For illustration of FIG. 8A, both Ω_{X}(t) and Ω_{Y}(t) are activated between time=0 and a time T2 and are deactivated after the time T2 and have zero value. Both Ω_{X}(t) and Ω_{y}(t) oscillate between a value M1 and a value M2. In some embodiments, M1 is equal to 1 millitesla (mT), M2 is equal to −1 mT, the time T1 is equal to 200 nanosecond (ns), and the time T2 is equal to 400 ns.

For illustration of FIG. 8A, a line LI corresponds to the time T1. The waveform of Ω_{X}(t) is symmetric with respect to the line L1, and the waveform of Ω_{Y}(t) is antisymmetric with respect to the line L1. Alternatively stated, the waveform of Ω_{X}(t) is symmetric with respect to the middle time point (time T1) of the quantum gate operation time (time T2), and the waveform of Ω_{Y}(t) is antisymmetric with respect to the middle time point (time T1) of the quantum gate operation time (time T2). In some embodiments, Ω_{X}(t) is referred to as a symmetric portion of the portion B2 of the magnetic field, and Ω_{Y}(t) is referred to as an antisymmetric portion of the portion B2 of the magnetic field.

In some embodiments, each of Ω_{X}(t) and Ω_{Y}(t) includes a combination of sinⁿ waves and is represented as the equations (3)-(4) below:

$$\begin{matrix}{Ω}_{X} ( t ) = {\sum }_{k = 1}^{{k}_{max}^{a}} {a}_{k} \cdot {sin}^{n} ( \frac{( 2 k - 1 ) π}{{t}_{f}} \cdot t ) & ( 3 ) \\ {Ω}_{Y} ( t ) = {\sum }_{k = 1}^{{k}_{max}^{b}} {b}_{k} \cdot {sin}^{n} ( \frac{( 2 k ) π}{{t}_{f}} \cdot t ) & ( 4 )\end{matrix}$$

in which n is a positive odd integer, aₖ and bₖ are control parameters, and t_{f} is the end time of Ω_{X}(t) and Ω_{Y}(t). In some embodiments of FIG. 8A, t_{f} is equal to the time T2. aₖ and bₖ are determined by the optimization method based on the infidelity the CNOT gate operation.

Based on the discussions made with references to FIGS. 4-7 and the equation (1), the voltage signals V1-V3 induces the coupling signal J, and the coupling signal J is represented as J(t) and is a function of time, as shown in equation (5) below:

$$J ( t ) = {\sum }_{k = 1}^{{k}_{max}^{c}} {c}_{k} \cdot {sin}^{2} ( \frac{k π}{{t}_{f}} \cdot t ) \qquad ( 5 )$$

cₖ is a control parameter, and t_{f} is the end time of Ω_{X}(t) and Ω_{Y}(t). As shown by the formula above, J(t) includes a combination of sine squared (sin²) waves. Alternatively stated, J(t) is a superposition of multiple sine squared wave. cₖ is determined by the optimization method based on the infidelity the CNOT gate operation. In some embodiments, at least the voltage signal V2 applied on the gate structure G2 has a waveform corresponding to the coupling signal J.

For illustration of FIG. 8B, J(t) is activated between time=0 and a time T2 and are zero at time=0 and the time T2. J(t) has a maximum value F1. The waveform of J(t) is symmetric with respect to the time T1.

In some embodiments, after the CNOT gate operation is performed, the spin states of the qubits Q1-Q2 can be measured via the charge sensor in the embodiments of FIGS. 4-7. The electron spin states are compared with theoretical outputs of the CNOT gate operation. The difference between the electron spin states read by the charge sensor and the theoretical outputs are configured to determine an infidelity of the CNOT gate operation by the methods of the randomized benchmarking, the gate set tomography, and/or other efficient schemes.

In some embodiments, the infidelity of the CNOT gate operation is configured to adjust the control parameters aₖ, bₖ, and cₖ through optimization algorithm. When the CNOT gate operation is performed with the adjusted control parameters aₖ, bₖ, and cₖ, the CNOT gate operation has an improved infidelity. In some embodiments, optimization algorithm includes, for example, non-gradient optimization algorithm, Nelder-Mead algorithm, etc.

In some embodiments, with the configurations of the present application, the CNOT gate operation has a fidelity larger than around 99.99%, and the charge noise can be effectively suppressed at the sweet spot.

Reference is now made to FIG. 9. FIG. 9 is a waveform diagram for the coupling signal J corresponding to that shown in FIGS. 5 and 7 for the CZ gate operation, in accordance with various embodiments of the present disclosure. As discussed above, the coupling signal J can be represented as J(t). When J(t)/2π has a waveform such as the one shown in FIG. 9, the quantum device 100 in FIGS. 4-5 or the quantum device 200 of FIGS. 6-7 is configured to perform the CZ gate operation to the qubits Q1-Q2.

For illustration of FIG. 9, J(t)/2π has a waveform of a rounded square wave that has two rounded corners C1 and C3. During the period between time=0 and a time T3, J(t)/2π is a sine squared wave rising from 0 to a value F2. During the period between the time T3 and a time T4, J(t)/2π is a square wave having the value F2. During the period between the time T4 and a time T5, J(t)/2π is a sine squared wave falling from the value F2 to 0. J(t)/2π can be represented as below:

$$\begin{matrix}J ( t ) = a \cdot {sin}^{2} ( \frac{1}{2} \frac{π}{T 3} \cdot t ) , for 0 \leq t \leq T 3 & ( 6 ) \\ J ( t ) = a , for T 3 \leq t \leq T 4 & ( 7 ) \\ J ( t ) = a \cdot {sin}^{2} ( \frac{1}{2} \frac{π}{T 3} \cdot ( t - T 4 ) + \frac{π}{2} ) , for T 4 \leq t \leq {t}_{f} & ( 8 )\end{matrix}$$

a is a control parameter, and t_{f} is the end time of J(t). In the embodiments of FIG. 9, t_{f} is equal to the time T5.

Alternatively stated, J(t)/2π includes a first sine squared wave during the period between time=0 and the time T3, a square wave during the period between the time T3 and the time T4, and a second squared wave during the period between the time T4 and the time T5. A combination of the first sine squared wave, the square wave, and the second sine squared wave has a waveform of a rounded square wave. The first sine squared wave and the second sine squared wave correspond to two rounded corners C1 and C3 of the rounded square wave. In some embodiments, at least the voltage signal V2 applied on the gate structure G2 has a waveform corresponding to the coupling signal J.

In some embodiments, to generate the coupling signal J of which J(t)/2π has a waveform as the one shown in FIG. 9, the first sine squared wave is first generated, the square wave is generated afterwards, and the second sine squared wave is generated lastly.

In some embodiments, the value F2 is around 12 Mega Hertz (MHz), and the time T5 is around 20 nanoseconds (ns). The configurations of the value F2 and the time T5 are given for illustrative purposes. In various embodiments, the value F2 and the time T5 can be adjusted according to the parameters of the quantum device used and/or the quantum gate to be performed.

In some approaches, a coupling signal of which J(t)/2π has a waveform of a square wave is configured to perform a CZ gate operation. The square wave does not have rounded corners such as the corners C1 and C3 as shown in FIG. 9. Due to the resolution and pixels of the pulse generator 12 used to generate J(t)/2π, the square wave generated by the pulse generator 12 is not smooth or continuous and has discrete values at the corners, and inconsistency exists between the expected square wave and the wave actually generated. Such inconsistency affects the fidelity of the CZ gate operation performed by the coupling signal J with a waveform of square wave.

With the configurations of the present application, as shown in FIG. 9, a zoom-in area C1′ corresponds to the corner C1, and a zoom-in area C2′ corresponds to a corner C2. As the zoom-in areas C1′ and C2′ show, the sine squared wave portion of J(t)/2π has smooth corners C1-C2. Alternatively stated, J(t)/2π is smooth and has continuous values at the corners C1 and C3, and the CZ gate operation performed by the coupling signal J with such waveform has a better fidelity, compared with the CZ gate operation in the some approaches.

In some embodiments, after the CZ gate operation is performed, the infidelity of the CZ gate operation is determined as described in previous embodiments. The determined infidelity of the CZ gate operation is configured to adjust the control parameter a through optimization algorithm. When the CZ gate operation is performed by the adjusted control parameter a, the CZ gate operation has an improved infidelity.

In some embodiments, through the coupling signal J having a waveform of J(t)/2π as shown in FIG. 9, the infidelity contribution from the filtering effect of the pulse generator 12 can be suppressed to below 10⁻⁶, and the infidelity contribution from the charge noise at the sweet spot can be suppressed to below 1.6×10⁻⁶.

Reference is now made to FIG. 10. FIG. 10 is a waveform diagram for the coupling signal J corresponding to that shown in FIGS. 5 and 7 for the CZ gate operation, in accordance with various embodiments of the present disclosure. When J(t)/2π has a waveform such as the one shown in FIG. 10, the quantum device 100 of FIGS. 4-5 and or the quantum device 200 of FIGS. 6-7 is configured to perform the CZ gate operate on the qubits Q1-Q2.

For illustration of FIG. 10, J(t)/2π has a waveform of a sine squared wave in the period between time=0 and a time T6. J(t)/2π oscillates between around a value F3 and 0. J(t)/2π can be represented as below:

$$J ( t ) = a \cdot {sin}^{2} ( \frac{2 π}{{t}_{f}} \cdot t ) \qquad ( 10 )$$

a is a control parameter, and t_{f} is the end time of J(t).

In some embodiments, F3 is around 25 MHZ, and the time T6 is around 25 ns.

In some embodiments, through the coupling signal J having a waveform of J(t)/2π as shown in FIG. 10, the infidelity contribution from the filtering effect of the pulse generator 12 can be suppressed to below 10⁻⁹, and the infidelity contribution from the charge noise at the sweet spot can be suppressed to around 3.5×10⁻⁶.

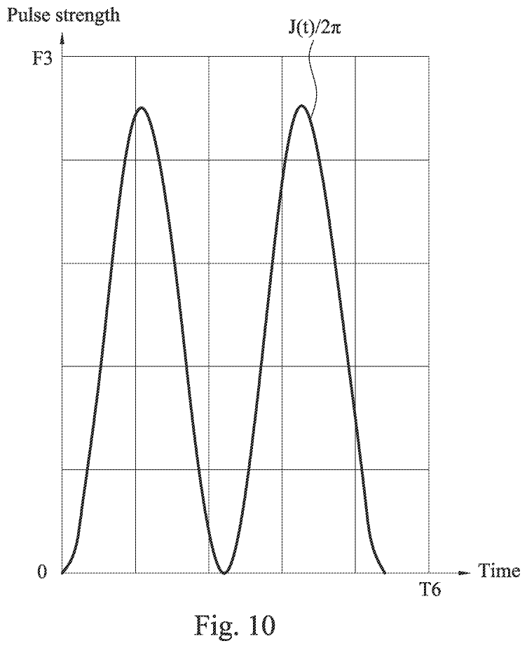

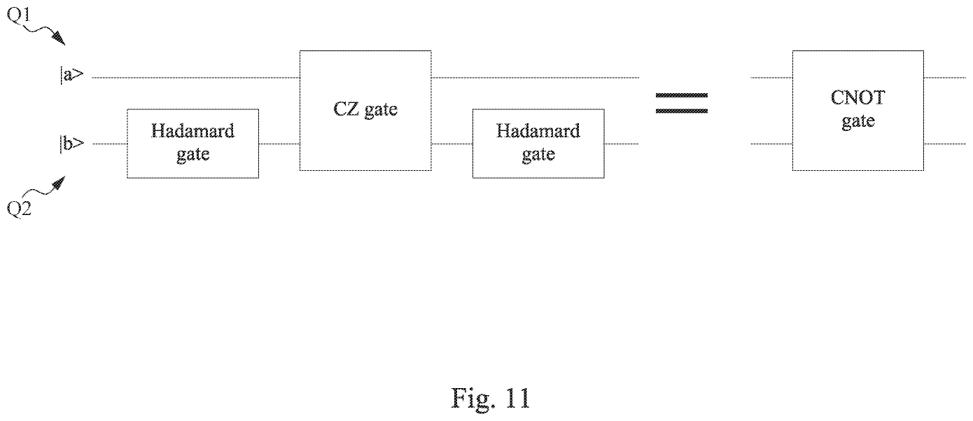

In some embodiments, with reference to FIG. 11, the CZ gate operation performed by the embodiments of FIGS. 9-10 can be extended to a composite CNOT gate operation by inserting single-qubit gate operations before and after the CZ gate operation. Specifically, the composite CNOT gate operation is performed by including a left single-qubit gate operation, a CZ gate operating operation after the left single-qubit gate operation, and a right single-qubit gate operation after the CZ gate operation. In some embodiments, the left and right single-qubit gate operations are both Hadamard(H) gate operation.

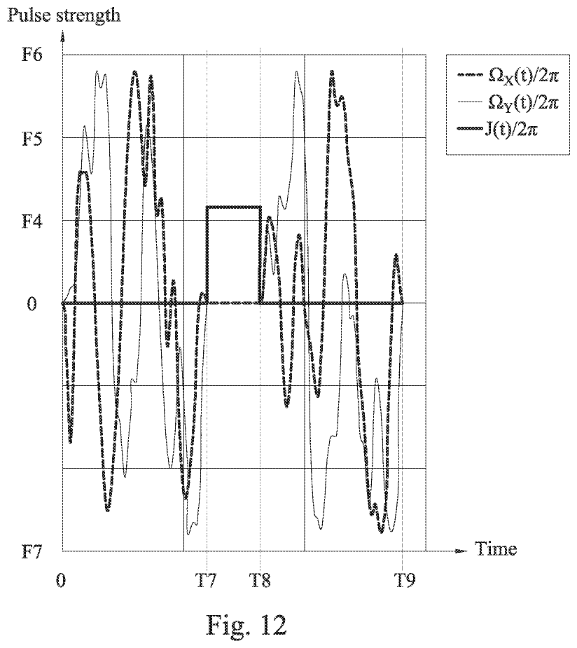

Reference is now made to FIG. 12 corresponding to the composite CNOT gate operation. FIG. 12 is a waveform diagram for the coupling signal J and the portion B2 of the magnetic field corresponding to those shown in FIGS. 4-7, in accordance with various embodiments of the present disclosure.

In some embodiments, the composite CNOT gate operation is performed by the portion B2 of the magnetic field with

$$\frac{{Ω}_{X} ( t )}{2 π} and \frac{{Ω}_{Y} ( t )}{2 π}$$

and the coupling signal J with

$$\frac{J ( t )}{2 π}$$

in FIG. 12, in which the composite CNOT gate operation includes a left single-qubit gate operation in a first time period, a CZ gate operation in a second time period following the first time period, and a right single-qubit gate operation in a third time period following the second time period. In some embodiments, the left and right single-qubit gate operations are both Hadamard(H) gate operations.

Specifically, in the embodiments of FIG. 12, the portion B2 of the magnetic field includes a portion corresponding to Ω_{X}(t) and a portion corresponding to Ω_{Y}(t). For illustration, during a period between time=0 and a time T7, both

$$\frac{{Ω}_{X} ( t )}{2 π} and \frac{{Ω}_{Y} ( t )}{2 π}$$

are activated to implement the single-qubit gate (e.g., H gate). During this period, Ω_{X}(t) has the portion Ω_{X}^{L}(t), and Ω_{Y}(t) has the portion Ω_{Y}^{L}(t).

$$\frac{J ( t )}{2 π}$$

is deactivated and is 0 in this period of time.

During the period between the time T7 and the time T8,

$$\frac{J ( t )}{2 π}$$

is configured to implement the CZ gate.

$$\frac{J ( t )}{2 π}$$

has a waveform that is substantially the same as the waveform of

$$\frac{J ( t )}{2 π}$$

as shown in FIG. 9. In addition,

$$\frac{{Ω}_{X} ( t )}{2 π} and \frac{{Ω}_{Y} ( t )}{2 π}$$

corresponding to the portion B2 of the magnetic field are 0. Alternatively stated, both

$$\frac{{Ω}_{X} ( t )}{2 π} and \frac{{Ω}_{Y} ( t )}{2 π}$$

are deactivated in this period of time.

During a period between the time T8 and a time T9,

$$\frac{{Ω}_{X} ( t )}{2 π} and \frac{{Ω}_{Y} ( t )}{2 π}$$

are configured to implement the other single-qubit (H) gate. During this period, Ω_{X}(t) has the portion Ω_{X}^{R}(t), and Ω_{Y}(t) has the portion Ω_{Y}^{R}(t).

$$\frac{J ( t )}{2 π}$$

is deactivated and is 0 in this period of time.

In some embodiments,

$$\frac{J ( t )}{2 π}$$

has a maximum value between values F4 and F5. In some embodiments, the value F4 is around 10 MHz, and the value F5 is around 20 MHz. In some embodiments, both

$$\frac{{Ω}_{X} ( t )}{2 π} and \frac{{Ω}_{Y} ( t )}{2 π}$$

oscillate between a value F6 and a value F7. In some embodiments, the value F6 is equal to 30 MHz, the value F7 is equal to −30 MHz, the time T7 is equal to 50 ns, the time T8 is equal to 100 ns, and the time T9 is equal to 150 ns. The configurations of the values F4-F7 and the times T7-T9 are given for illustrative purposes. In various embodiments, the values F4-F7 and the times T7-T9 can be adjusted according to the parameters of the quantum device used and/or the quantum gate to be performed.

According to the embodiments of FIG. 12, Ω_{X}(t) includes a portion Ω_{X}^{L}(t) in the period between time=0 and the time T7 and a portion Ω_{X}^{R}(t) in the period between the time T8 and the time T9. Ω_{Y}(t) includes a portion Ω_{Y}^{L}(t) in the period between time=0 and the time T7 and a portion Ω_{Y}^{R}(t) in the period between the time T8 and the time T9. In some embodiments, each of Ω_{X}^{L}(t), Ω_{Y}^{L}(t), Ω_{X}^{R}(t), and Ω_{Y}^{R}(t) includes a combination of sinⁿ waves and are represented as the formulas below:

$$\begin{matrix}{Ω}_{X}^{L} ( t ) = {\sum }_{k = 1}^{{k}_{max}^{a}} {a}_{k} \cdot {sin}^{n} ( \frac{k π}{{t}_{f}} \cdot t ) & ( 11 ) \\ {Ω}_{Y}^{L} ( t ) = {\sum }_{k = 1}^{{k}_{max}^{b}} {b}_{k} \cdot {sin}^{n} ( \frac{k π}{{t}_{f}} \cdot t ) & ( 12 ) \\ {Ω}_{X}^{R} ( t ) = {\sum }_{k = 1}^{{k}_{max}^{a} ′} {a}_{k}^{′} \cdot {sin}^{n} ( \frac{k π}{{t}_{f}} \cdot t ) & ( 13 ) \\ {Ω}_{Y}^{R} ( t ) = {\sum }_{k = 1}^{{k}_{max}^{b} ′} {b}_{k}^{′} \cdot {sin}^{n} ( \frac{k π}{{t}_{f}} \cdot t ) & ( 14 )\end{matrix}$$

n is a positive odd integer, aₖ, a′ₖ, bₖ, and b′ₖ are control parameters, and t_{f} is the end time of Ω_{X}^{L}(t), Ω_{Y}^{L}(t), Ω_{X}^{R}(t) and Ω_{Y}^{R}(t).

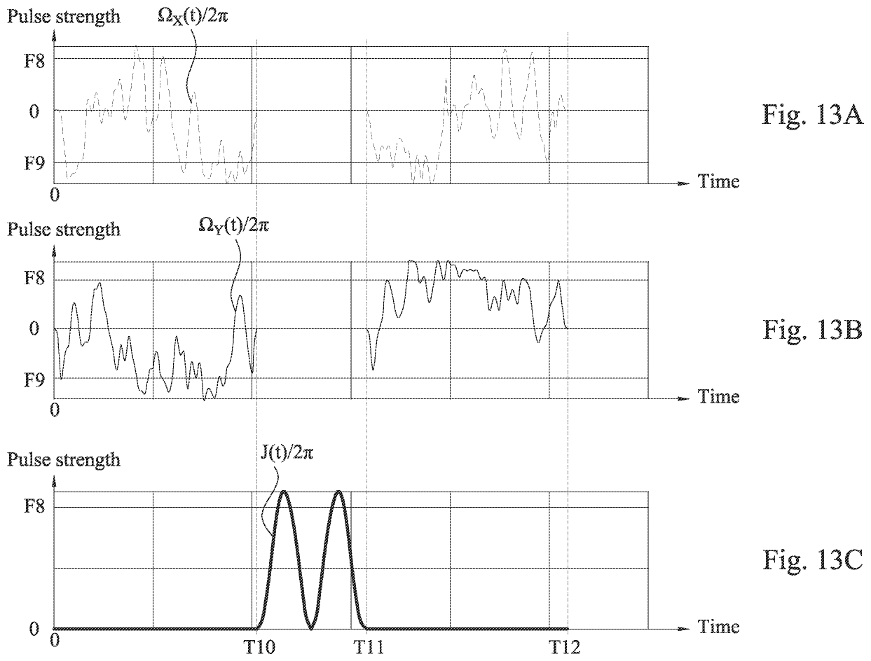

Another embodiments of the composite CNOT gate operation is discussed with reference to FIGS. 13A-13C. FIG. 13A is a waveform diagram for a portion Ω_{X}(t) of the portion B2 of the magnetic field corresponding to that shown in FIGS. 4 and 6, FIG. 13B is a waveform diagram for a portion Ω_{Y}(t) of the portion B2 of the magnetic field corresponding to that shown in FIGS. 4 and 6, in accordance with some embodiments of the present disclosure.

As shown by the formula discussed above, the portion B2 of the magnetic field includes a portion corresponding to Ω_{X}(t) and a portion corresponding to Ω_{Y}(t). For illustration of FIGS. 13A-13B, both

$$\frac{{Ω}_{X} ( t )}{2 π} and \frac{{Ω}_{Y} ( t )}{2 π}$$

are activated during a period between time=0 and a time T10, are deactivated and are 0 during a period between the time T10 and a time T11, and are activated during a period between the time T11 and a time T12. Both

$$\frac{{Ω}_{X} ( t )}{2 π} and \frac{{Ω}_{Y} ( t )}{2 π}$$

oscillate between a value F8 and a value F9.

In some embodiments, the value F8 is equal to 20 MHz, the value F9 is equal to −20 MHZ, the time T10 is around 40 ns, the time T11 is around 60 ns, and the time T12 is equal to 100 ns.

In some embodiments, Ω_{X}(t) includes a portion Ω_{X}^{L}(t) in the period between time=0 and the time T10 and a portion Ω_{X}^{R}(t) in the period between the time T11 and the time T12. Ω_{Y}(t) includes a portion Ω_{Y}^{L}(t) in the period between time=0 and the time T10 and a portion Ω_{Y}^{R}(t) in the period between the time T11 and the time T12.

In some embodiments, Ω_{X}^{L}(t), Ω_{Y}^{L}(t), Ω_{X}^{R}(t), and Ω_{Y}^{R}(t) have the same mathematical representations as the equations (11)-(14) discussed in the previous embodiments of FIG. 12. Details of the embodiments of FIG. 12 can be referred to in understanding FIGS. 13A-13B.

Reference is now made to FIG. 13C. FIG. 13C is a waveform diagram for the coupling signal J, in accordance with some embodiments of the present disclosure.

For illustration of FIG. 13C,

$$\frac{J ( t )}{2 π}$$

is deactivated and is 0 during the period between time=0 and the time T10, is activated during the period between the time T10 and the time T11, and is deactivated and is 0 during the period between the time T11 and the time T12.

$$\frac{J ( t )}{2 π}$$

has a maximum value around a value F8. In some embodiments, the value F8 is around 20 MHz.

In some embodiments, during the period between the time T10 and the time T11,

$$\frac{J ( t )}{2 π}$$

has a waveform that is substantially the same as the waveform of

$$\frac{J ( t )}{2 π}$$

as shown in FIG. 10. Alternatively stated,

$$\frac{J ( t )}{2 π}$$

as shown in FIG. 13C is a sine squared wave during the period between the time T10 and the time T11. Previous discussion regarding

$$\frac{J ( t )}{2 π}$$

as shown in FIG. 10 in understanding

$$\frac{J ( t )}{2 π}$$

as shown in FIG. 13C.

In some embodiments,

$$\frac{{Ω}_{X} ( t )}{2 π} and \frac{{Ω}_{Y} ( t )}{2 π}$$

as shown in FIGS. 13A-13B and

$$\frac{J ( t )}{2 π}$$

as shown in FIG. 13C are configured to implement the composite CNOT gate. Specifically, During the period between time=0 and the time T10,

$$\frac{{Ω}_{X} ( t )}{2 π} and \frac{{Ω}_{Y} ( t )}{2 π}$$

are configured to implement the left single-qubit gate. During this period, Ω_{X}(t) has the portion Ω_{X}^{L}(t), and Ω_{Y}(t) has the portion Ω_{Y}^{L}(t). During the period between the time T10 and the time T11,

$$\frac{J ( t )}{2 π}$$

is configured to implement the CZ gate, and

$$\frac{{Ω}_{X} ( t )}{2 π} and \frac{{Ω}_{Y} ( t )}{2 π}$$

corresponding to the portion B2 of the magnetic field are 0. During the period between the time T11 and the time T12,

$$\frac{{Ω}_{X} ( t )}{2 π} and \frac{{Ω}_{Y} ( t )}{2 π}$$

are configured to implement the right single-qubit gate. During this period, Ω_{X}(t) has the portion Ω_{X}^{R}(t), and Ω_{Y}(t) has the portion Ω_{Y}^{R}(t). In some embodiments, the left and right single-qubit gates are both Hadamard gates.

In some embodiments, after the composite CNOT gate operation is performed by the portion B2 of the magnetic field with Ω_{X}(t) and Ω_{Y}(t) and the coupling signal J with J(t) as shown in FIG. 12 or in FIGS. 13A-13C, the infidelity of the composite CNOT gate operation is determined as described in previous embodiments. The determined infidelity of the composite CNOT gate operation is configured to adjust the control parameter a in the CZ gate operation, the control parameters aₖ and bₖ in the left single-qubit gate, and the control parameters a′ₖ and b′ₖ in the right single-qubit gate through optimization algorithm. When the composite CNOT gate operation is performed with he adjusted control parameters a, aₖ, bₖ, a′ₖ, and b′ₖ, the composite CNOT gate operation has an improved infidelity.

In some embodiments, by the portion B2 of the magnetic field with Ω_{X}(t) and Ω_{Y}(t) and the coupling signal J with J(t) as shown in FIG. 12 or in FIGS. 13A-13C, both charge noise and dephasing noise can be suppressed at the sweet spot.

In some embodiments, the composite CNOT gate operation of embodiments of FIG. 12 or of FIGS. 13A-13C has a fidelity larger than 99.99%.

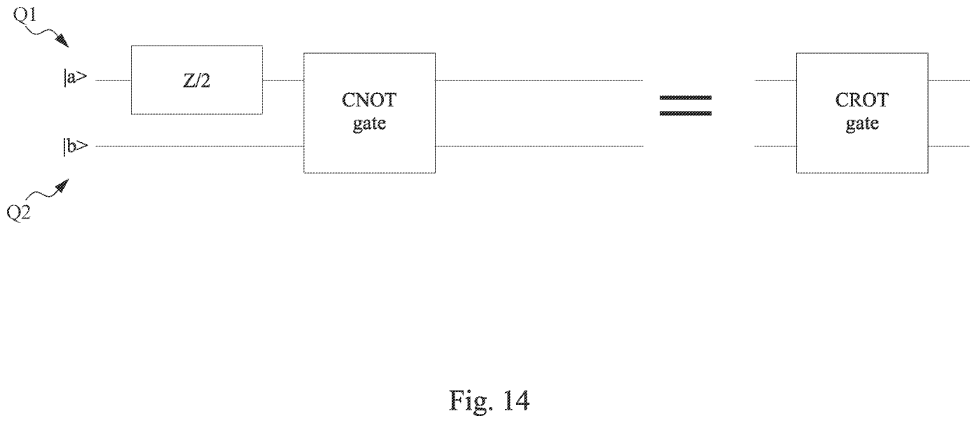

In some embodiments, the CZ gate operation and/or the CNOT gate operation disclosed above is able to combine with other quantum gate(s) operation. For example, as shown in the embodiments of FIG. 14, the CNOT gate operation, including the composite CNOT gate operation, performed by the embodiments of FIGS. 8A-8B, 12, and 13A-13C can be extended to a CROT gate operation by inserting a single-qubit Z/2 gate operation.

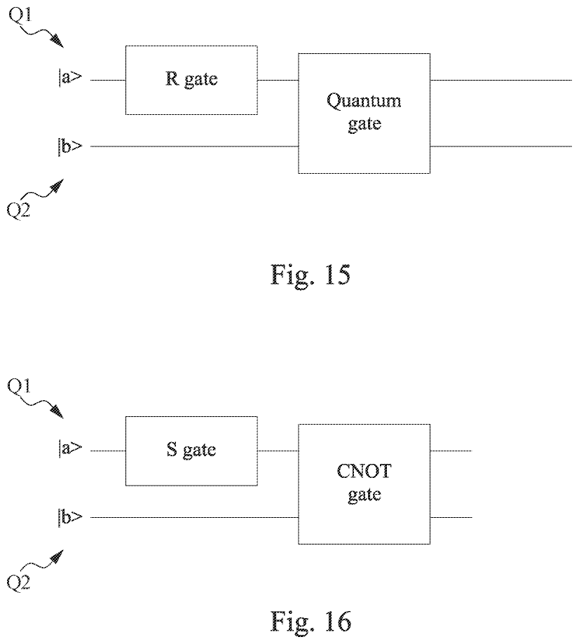

In some embodiments, any unitary operation or quantum gate can be constructed using the CZ gate operation or the CNOT gate operation performed by the previous embodiments and single-qubit rotations. As shown in FIGS. 15-18, any unitary operation can be approximated to arbitrary precision by using various gates.

In the embodiments of FIG. 15, a R gate of the rotation operator is inserted before a quantum gate operation is performed to the qubits Q1-Q2. The quantum gate includes one of the CZ gate operation and the CNOT gate operation in the aforementioned embodiments of FIGS. 8A-13C. In some embodiments, The R gate operation is a single-qubit rotation through angle θ (radians) around the y-axis or z-axis.

In the embodiments of FIG. 16, an S gate operation of the rotation operator is inserted before the CNOT gate operation to perform the quantum operation to the qubits Q1-Q2. The CNOT gate operation is performed according to the aforementioned embodiments of FIGS. 8A-8B, 12, and 13A-13C. In some embodiments, The S gate operation is a single-qubit operation and also referred to as a phase gate operation or the Z90 gate operation because it represents a 90-degree rotation around the z-axis.

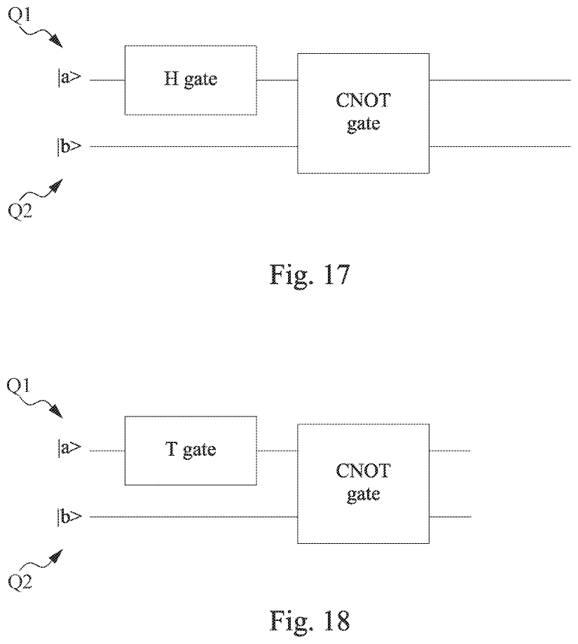

In the embodiments of FIG. 17, a Hadamard(H) gate operation of the rotation operator is inserted before the CNOT gate operation to perform the quantum operation to the qubits Q1-Q2. The CNOT gate operation is performed according to the aforementioned embodiments of FIGS. 8A-8B, 12, and 13A-13C. In some embodiments, The H gate operation is a single-qubit operation that maps the basis state

$$\vert 0 〉 to ( \vert 0 〉 + \frac{\vert 1 〉 )}{\sqrt{2}} and \vert 1 〉 to ( \vert 0 〉 - \frac{\vert 1 〉 )}{\sqrt{2}} ,$$

creating an equal superposition of the two basis states.

In the embodiments of FIG. 18, a T gate operation of the rotation operator is inserted before the CNOT gate operation to perform the quantum operation to the qubits Q1-Q2. The CNOT gate is implemented according to the aforementioned embodiments of FIGS. 8A-8B, 12, and 13A-13C. In some embodiments, The T gate operation is a single-qubit operation and is related to the S gate operation by the relationship S=T².

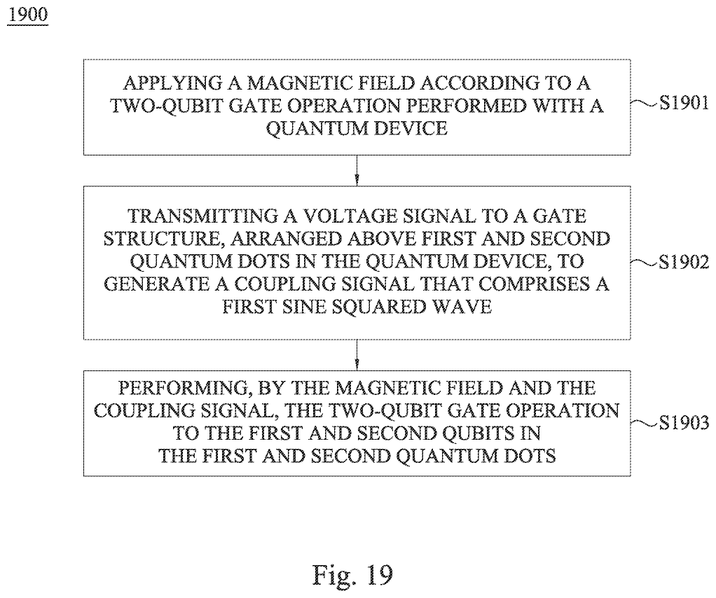

Reference is now made to FIG. 19. FIG. 19 is a flowchart of a method 1900 for quantum computation, in accordance with some embodiments of the present disclosure. The method 1900 includes steps S1901-1903.

In step S1901, a magnetic field according to a two-qubit gate operation performed with a quantum device is applied to the quantum device. For example, in the embodiments of FIGS. 4-5, the magnetic field including the portions B1 and B2 is applied to the quantum device 100. In the embodiments of FIGS. 8A-8B, 12, 13A-13C, the applied magnetic field is based on the CNOT gate operation. In the embodiments of FIGS. 9-10, the applied magnetic field is based on the CZ gate operation, in which the portion B2 of the magnetic field is 0 according to the CZ gate operation.

In some embodiments, the portion B2 of the magnetic field has a time-varying portion that includes a symmetric composite portion and an antisymmetric composite portion different from the symmetric composite portion. For example, as shown in FIG. 8A, the values of Ω_{X}(t) and Ω_{Y}(t) of the portion B2 of the magnetic field vary with time, in which Ω_{X}(t) is symmetric with respect to the time T1 and different from Ω_{Y}(t), being antisymmetric with respect to the time T1.

In step S1902, a voltage signal is transmitted to a gate structure to generate a coupling signal J, and the gate structure is arranged above first and second quantum dots. The coupling signal J includes a first sine squared wave. For example, in the embodiments of FIGS. 4-8B, the voltage signals V1-V3 are transmitted to the gate structures G1-G3 arranged above the quantum dots QD1-QD2 to generate the couple signal J that includes at least one sine squared wave. In some embodiments, as shown in FIGS. 9 and 12, the coupling signal J with

$$\frac{J ( t )}{2 π}$$

includes a combination of the first sine squared wave, the square wave, and the second sine squared wave. In various embodiments, as shown in FIGS. 10 and 13C, the coupling signal J with

$$\frac{J ( t )}{2 π}$$

includes a sine squared wave.

In step S1903, the two-qubit gate operation is performed, by the magnetic field and the coupling signal, to the first and second qubits in the first and second quantum dots. As shown in the embodiments of FIGS. 4-13C, the CNOT gate operation or the CZ gate operation is performed to the qubits Q1-Q2 in the quantum dots QD1-QD2 in the quantum devices 100 or 200.

In some embodiments, as shown in FIGS. 8A-8B, the operation of transmitting the voltage signal to generate the coupling signal J and the operation of applying the magnetic field are performed during a same time period, for example, between time=0 and the time T2.

In some embodiments, the coupling signal J further includes at least one second sine squared wave. The at least one second sine squared wave superposes on the first sine squared wave. For example, in the embodiments of FIG. 8B, J(t) includes a combination of sine squared waves.

In some embodiments, the coupling signal J includes the first sine squared wave in a first time period, a square wave in a second time period following the first time period, and a second sine squared wave in a third time period following the second time period. A combination of the first sine squared wave, the square wave, and the second sine squared wave has a waveform of a rounded square wave, and the first sine squared wave and the second sine squared wave correspond to two rounded corners of the rounded square wave. For example, as shown in FIG. 9. J(t)/2π includes a first sine squared wave corresponding to the round corner C1 during the period between time=0 and the time T3, a square wave during the period between the time T3 and the time T4, and a second squared wave during the period between the time T4 and the time T5 corresponding to the round corner C3.

Continually, the portion of the magnetic field includes a first portion in a fourth time period and a second portion in a fifth time period. The fourth time period is followed by the first time period discussed in the last paragraph, and the fifth time period follows the third time period discussed in the last paragraph. For instance, as shown in FIG. 12, each of the

$$\frac{{Ω}_{X} ( t )}{2 π} and \frac{{Ω}_{Y} ( t )}{2 π}$$

includes a portion during the period between time=0 and the time T7 and a portion during the period between the time T8 and the time T9. The period between time=0 and the time T7 is followed by the period between the time T7 and the time T8, and the period between the time T8 and the time T9 follows the period between the time T7 and the time T8. The period between the time T7 and the time T8 corresponds to the period between time=0 and the time T5 in the embodiments of FIG. 9.

In some embodiments, the first sine squared wave is activated during a time period, and the at least one portion of the external magnetic field is deactivated during the time period and is activated before and after the time period. The portion of the magnetic field comprises a first composite portion and a second composite portion, and each of the first composite portion and the second composite portion comprises a combination of sinⁿ waves, n being a positive odd integer. For example, in the embodiments of FIGS. 13A-13C, J(t)/2π with the waveform of a sine squared wave is activated during the period between the time T10 and the time T11, and the

$$\frac{{Ω}_{X} ( t )}{2 π} and \frac{{Ω}_{Y} ( t )}{2 π}$$

of the portion B2 of the magnetic field are deactivated during the period between the time T10 and the time T11 and are activated before and after the period between the time T10 and the time T11. Each of

$$\frac{{Ω}_{X} ( t )}{2 π} and \frac{{Ω}_{Y} ( t )}{2 π}$$

of the portion B2 of the magnetic field includes a combination of sinⁿ waves, n being a positive odd integer.

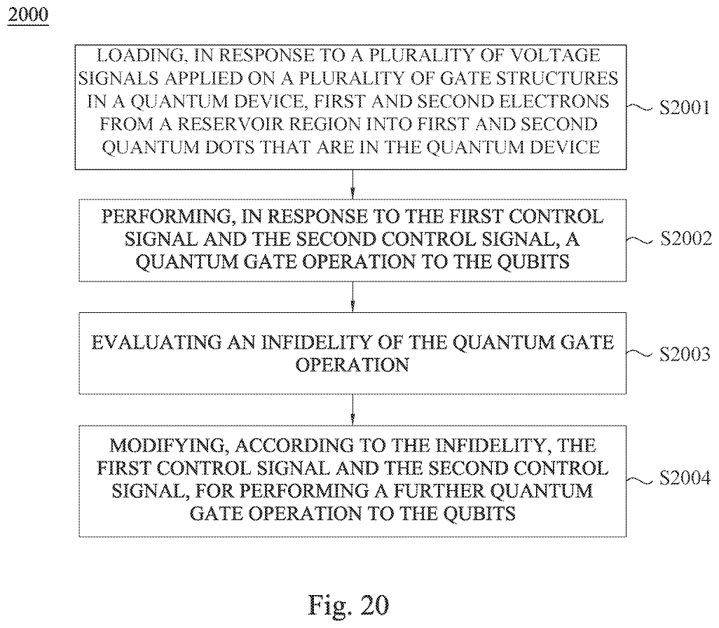

Reference is now made to FIG. 20. FIG. 20 is a flowchart of a method 2000 for quantum computation, in accordance with some embodiments of the present disclosure. The method 2000 includes steps S2001-S2003.

In the step S2001, a first control signal including a combination of sin^{m} pulses and a second control signal including a symmetric composite portion are provided to qubits. The qubits correspond to quantum dots, as shown in the embodiments of FIGS. 3-7. m is a positive even integer. For example, the first control signal includes the coupling signal J and the second control signal includes the magnetic field. The symmetric composite portion is symmetric with respect to the middle time point of the symmetric composite portion. For example, the coupling signal J, e.g., in FIGS. 3-7, 8B, 12, 13C, having the combination of sin² pulses and the portion B2 of the magnetic field including Ω_{X}(t) portion are provided to the qubits Q1-Q2. Ω_{X}(t) portion is symmetric with respect to the middle time point (time T1) of Ω_{X}(t) portion.

In some embodiments, the second control signal further comprises an antisymmetric composite portion being antisymmetric with respect to the middle time point of the antisymmetric composite portion. The first control signal and the symmetric and antisymmetric composite portions of the second control signal are activated during a same time period. For example, in the embodiments of in FIGS. 8A-8B, the Ω_{Y}(t) portion of the portion B2 of the magnetic field is antisymmetric with respect to the middle time point (time T1) of the Ω_{Y}(t) portion. Ω_{X}(t), Ω_{y}(t), and J(t) are activated during a same time period.

In some embodiments, the operation of providing the first control signal includes providing a first sin^{m} pulse, providing a square pulse after providing the first sin^{m} pulse, and providing a second sin^{m} pulseafter providing the square pulse. Specifically, in the embodiments of FIG. 12, to provide the coupling signal J with

$$\frac{J ( t )}{2 π} ,$$

a first sine squared (sin²) pulse is first provided, a square pulse is then provided, and a second sine squared pulse is lastly provided. As discussed in the embodiments of FIG. 12, a first sine squared (sin²) pulse in the coupling signal J is first provided, a square pulse is then provided, and a second sine squared pulse is lastly provided.

In the step S2002, in response to the first and second control signals, a quantum gate operation is performed to the qubits. For example, as discussed in the embodiments of FIGS. 8A-8B, a CNOT gate operation is performed to the qubits Q1-Q2 in response to the coupling signal J with J(t) and the portion B2 of the magnetic field with Ω_{X}(t) and Ω_{Y}(t). In the embodiments of FIG. 12 or FIGS. 13A-13C, a composite CNOT gate operation is performed to the qubits Q1-Q2 in response to the coupling signal J with J(t) and the portion B2 of the magnetic field with Ω_{X}(t) and Ω_{Y}(t).

In step S2003, the infidelity of the quantum gate operation is evaluated by reading the electron spin states of the quantum dots QD1-QD2, and comparing the electron spin states with theoretical values. The difference between the measured electron spin states and the theoretical values is configured to determine the infidelity of the quantum gate operation by the methods of the randomized benchmarking, the gate set tomography, and/or other efficient schemes. In some embodiments, the information including system parameters and the noise spectra of the system in which the quantum gate operation is performed are collected for evaluation.

In step S2004, according to the infidelity, the first and second control signals are modified according to the infidelity. For example, the control parameters of the coupling signal J with J(t) and the portion B2 of the magnetic field with Ω_{X}(t) and Ω_{Y}(t) as shown in FIGS. 8A-8B, 12, 13A-13C are modified according to the infidelity of the quantum gate operation, in order to obtain the optimized control parameters for improving the fidelity of the quantum gate operation. In some embodiments, a corresponding quantum gate operation is performed by the first and second control signals with optimized control parameters.

In some embodiments, modifying the first and second control signals includes modifying a parameter corresponding to a maximum value of the first and second sin^{m} pulses and the square pulse. Specifically, in the embodiments of FIG. 12, the control parameter a corresponds to the maximum value of the two sine squared pulses and the square pulse, which is around the value F2. The control parameter a is modified according to the infidelity.

In some embodiments, the second control signal further includes first and second amplitude portions, the first amplitude portion includes first and second composite portions, the second amplitude portion includes third and fourth composite portions. Each of the first composite portion, the second composite portion, the third composite portion, and the fourth composite portion comprises a combination of sin^{m} waves, and n is a positive odd integer. Specifically, in the embodiments of FIGS. 12, 13A-13C, the portion B2 of the magnetic field includes Ω_{X}(t) and Ω_{Y}(t). Ω_{X}(t) includes Ω_{X}^{L} and Ω_{X}^{R} composite portions, and Ω_{Y}(t) includes Ω_{Y}^{L} and Ω_{Y}^{R} composite portions. Each of Ω_{X}^{L}, Ω_{X}^{R}, Ω_{Y}^{L}, and Ω_{Y}^{R} includes a combination of sinⁿ waves, and n is a positive odd integer.

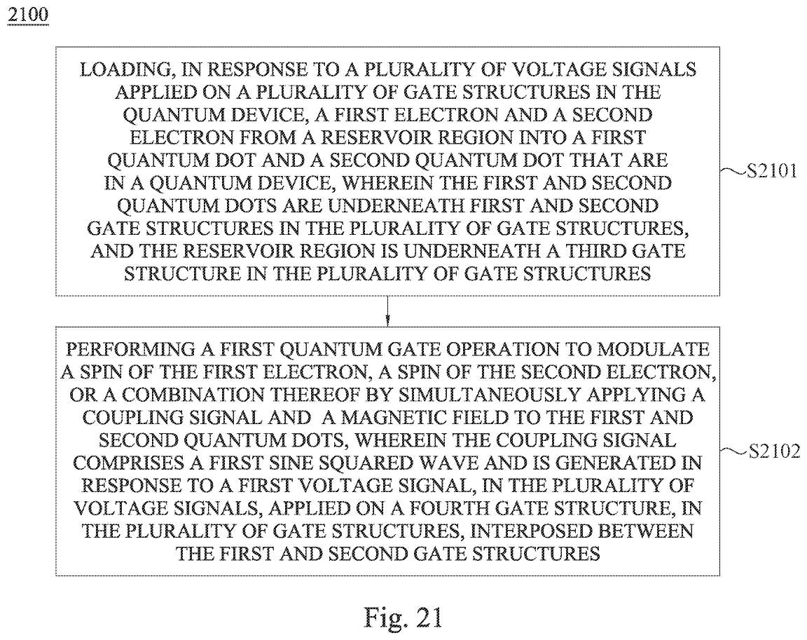

Reference is now made to FIG. 21. FIG. 21 is a flowchart of a method 2100 for quantum computation, in accordance with some embodiments of the present disclosure. The method 2100 includes steps S2101-S2102.

In the step S2101, as shown in FIG. 5, electrons E1-E2 from the electron reservoir 124 are loaded into the quantum dots QD1-QD2 in response to the voltage signals applied on the gate structures G1-G5 in the quantum device 100. In the embodiments of FIG. 5, the quantum dots QD1-QD2 are underneath the gate structures G1 and G3 respectively, and the electron reservoir 124 is underneath the gate structure RG.

In the step S2102, a first quantum gate operation is performed to modulate a spin of the electron E1, a spin of the electron E2, or a combination thereof by simultaneously applying the coupling signal J and the magnetic field to the quantum dots QD1-QD2. The coupling signal J includes a first sine squared wave and is generated in response to the voltage signal V2 applied on the gate structure G2 which is interposed between the gate structures G1 and G3. As aforementioned embodiments, the first quantum gate operation includes the CZ gate operation or the CNOT gate operation.

In some embodiments, as discussed in the embodiments of the CNOT gate operation in FIGS. 8A-8B, the coupling signal J is a combination of the first sine squared wave and at least one second sine squared wave, the portion B2 of the magnetic field includes a combination of sinⁿ waves, and n is a positive odd integer.

In some embodiments of the CZ gate operation, for example in FIG. 9, the coupling signal J further includes a second sine squared wave, and the first and second sine squared waves are activated in a sequential order and have a same maximum value. As discussed in the embodiments of FIG. 9, the first sine squared wave is activated first during the period between time=0 and the time T3, and the second sine squared wave is then activated during the period between the time T4 and the time T5. In addition, in the embodiments of FIG. 10, the waveform of

$$\frac{J ( t )}{2 π}$$

can also be represented as two sine squared waves that are activated in a sequential order.

In some embodiments as shown in FIG. 11, the method 2100 further includes: performing a second quantum gate operation (e.g., the hadamard gate operation) on the spin of the electron E2 before performing the CZ quantum gate operation for performing the CNOT quantum gate operation to the spin of the electron E1 and the spin of the electron E2. In the embodiments shown in FIG. 14, the single-qubit Z/2 gate operation is performed to the spin of the electron E1 before performing the CNOT quantum gate operation for performing the CROT quantum gate operation to the spin of the electron E1 and the spin of the electron E2.

In some embodiments, the composite CNOT gate operation is performed by performing a left single-qubit gate operation, the CZ gate operation, and the right single-qubit gate operation in a sequential order. When the left and right single-qubit gate operations are performed, the coupling signal J is deactivated, and the portion B2 of the magnetic field is activated. When the CZ gate operation is performed, the coupling signal J is activated, and the portion B2 of the magnetic field is deactivated. The portion B1 of the magnetic field is activated constantly.

In conclusion, the present disclosure uses the coupling signal J and the portion B2 of the magnetic field with specific waveforms to implement two-qubit gate with high fidelity. This gate fidelity improvement can substantially increase the reliable circuit depths for noisy intermediate-scale quantum (NISQ) devices, and can significantly reduce the number of physical qubits required for implementing error-corrected logical qubits for large-scale fault-tolerant quantum computation.

A method is provided, including: applying a magnetic field according to a two-qubit gate operation performed with a quantum device; transmitting a voltage signal to a gate structure, arranged above first and second quantum dots in the quantum device, to generate a coupling signal that includes a first sine squared wave; and performing, by the magnetic field and the coupling signal, the two-qubit gate operation to the first and second qubits in the first and second quantum dots.

In some embodiments, an alternating portion of the magnetic field has a time-varying portion that includes a symmetric composite portion and an antisymmetric composite portion different from the symmetric composite portion, the symmetric composite portion being symmetric with respect to a middle time point of the symmetric composite portion.

In some embodiments, each of the symmetric composite portion and the antisymmetric composite portion includes a combination of sinⁿ waves, and n is an odd integer.

In some embodiments, the operation of transmitting the voltage signal to generate the coupling signal and the operation of applying the magnetic field to the first and second qubits are performed during a same time period.

In some embodiments, the coupling signal further includes at least one second sine squared wave superposing on the first sine squared wave.

In some embodiments, the coupling signal includes the first sine squared wave in a first time period and a square wave in a second time period following the first time period.

In some embodiments, the coupling signal further includes a second sine squared wave in a third time period following the second time period.

In some embodiments, a combination of the first sine squared wave, the square wave, and the second sine squared wave has a waveform of a rounded square wave, and the first sine squared wave and the second sine squared wave correspond to two rounded corners of the rounded square wave.

In some embodiments, the magnetic field includes a first portion in a fourth time period followed by the first time period and a second portion in a fifth time period following the third time period.

In some embodiments, the first sine squared wave is activated during a time period, and the magnetic field is deactivated during the time period and is activated before and after the time period.

In some embodiments, an alternating portion of the magnetic field includes a first composite portion and a second composite portion. Each of the first composite portion and the second composite portion includes a combination of sinⁿ waves, and n is an odd integer.

A method is provided, including: providing qubits which correspond to quantum dots in a quantum device, with a first control signal including a combination of sin^{m} pulses, m being an even integer, and a second control signal including a symmetric composite portion, the symmetric composite portion being symmetric with respect to a middle time point of the symmetric composite portion; performing, in response to the first control signal and the second control signal, a quantum gate operation to the qubits; evaluating an infidelity of the quantum gate operation; and modifying, according to the infidelity, the first control signal and the second control signal, for performing a further quantum gate operation to the qubits.

In some embodiments, the second control signal further includes an antisymmetric composite portion being antisymmetric with respect to the middle time point. The first control signal and the symmetric and antisymmetric composite portions of the second control signal are activated during a same time period.

In some embodiments, the operation of providing the first control signal includes providing a first sin^{m} pulse; providing a square pulse after providing the first sin^{m} pulse; and providing a second sin^{m} pulse providing the square pulse.

In some embodiments, the operation of modifying the first and second control signals includes modifying a parameter corresponding to a maximum value of the first and second sin^{m} pulses and the square pulse.

In some embodiments, the second control signal further includes first and second amplitude portions. The first amplitude portion includes first and second composite portions, and the second amplitude portion includes third and fourth composite portions. Each of the first composite portion, the second composite portion, the third composite portion, and the fourth composite portion includes a combination of sinⁿ waves, and n is an odd integer.

A method is provided, including: loading, in response to a plurality of voltage signals applied on a plurality of gate structures in the quantum device, a first electron and a second electron from a reservoir region into a first quantum dot and a second quantum dot that are in a quantum device; and performing a first quantum gate operation to modulate a spin of the first electron, a spin of the second electron, or a combination thereof by simultaneously applying a coupling signal and a magnetic field to the first and second quantum dots. The first and second quantum dots are underneath first and second gate structures in the plurality of gate structures, and the reservoir region is underneath a third gate structure in the plurality of gate structures. The coupling signal includes a first sine squared wave and is generated in response to a first voltage signal, in the plurality of voltage signals, applied on a fourth gate structure, in the plurality of gate structures, interposed between the first and second gate structures.

In some embodiments, the coupling signal is a combination of the first sine squared wave and at least one second sine squared wave, and the magnetic field includes a combination of sinⁿ waves, and n is an odd integer. The first quantum gate operation is a controlled-NOT (CNOT) quantum gate operation.

In some embodiments, the coupling signal further includes a second sine squared wave. The first and second sine squared waves are activated in a sequential order and have a same maximum value, and the first quantum gate operation is a controlled-Z (CZ) quantum gate operation.

In some embodiments, the method further includes performing a second quantum gate operation on the spin of one of the first and second electrons before performing the first quantum gate operation for performing a third quantum gate operation to the spin of the first electron, the spin of the second electron, or the combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
applying a magnetic field according to a two-qubit gate operation performed with a quantum device;
transmitting a voltage signal to a gate structure, arranged above first and second quantum dots in the quantum device, to generate a coupling signal that comprises a first sine squared wave; and
performing, by the magnetic field and the coupling signal, the two-qubit gate operation to first and second qubits in the first and second quantum dots.

2. The method of claim 1, wherein an alternating portion of the magnetic field has a time-varying portion that comprises a symmetric composite portion and an antisymmetric composite portion different from the symmetric composite portion, the symmetric composite portion being symmetric with respect to a middle time point of the symmetric composite portion.

3. The method of claim 2, wherein each of the symmetric composite portion and the antisymmetric composite portion comprises a combination of sinⁿ waves, and n is an odd integer.

4. The method of claim 1, wherein the operation of transmitting the voltage signal to generate the coupling signal and the operation of applying the magnetic field to the first and second qubits are performed during a same time period.

5. The method of claim 1, wherein the coupling signal further comprises at least one second sine squared wave superposing on the first sine squared wave.

6. The method of claim 1, wherein the coupling signal comprises the first sine squared wave in a first time period and a square wave in a second time period following the first time period.

7. The method of claim 6, wherein the coupling signal further comprises a second sine squared wave in a third time period following the second time period.

8. The method of claim 7, wherein a combination of the first sine squared wave, the square wave, and the second sine squared wave has a waveform of a rounded square wave, and the first sine squared wave and the second sine squared wave correspond to two rounded corners of the rounded square wave.

9. The method of claim 7, wherein the magnetic field comprises a first portion in a fourth time period followed by the first time period and a second portion in a fifth time period following the third time period.

10. The method of claim 1, wherein the first sine squared wave is activated during a time period, and
the magnetic field is deactivated during the time period and is activated before and after the time period.

11. The method of claim 10, wherein an alternating portion of the magnetic field comprises a first composite portion and a second composite portion,
wherein each of the first composite portion and the second composite portion comprises a combination of sinⁿ waves, and n is an odd integer.

12. A method, comprising:
providing qubits which correspond to quantum dots in a quantum device, with a first control signal comprising a combination of sin^{m} pulses, m being an even integer, and a second control signal comprising a symmetric composite portion, the symmetric composite portion being symmetric with respect to a middle time point of the symmetric composite portion;
performing, in response to the first control signal and the second control signal, a quantum gate operation to the qubits;
evaluating an infidelity of the quantum gate operation; and
modifying, according to the infidelity, the first control signal and the second control signal, for performing a further quantum gate operation to the qubits.

13. The method of claim 12, wherein the second control signal further comprises an antisymmetric composite portion being antisymmetric with respect to the middle time point,
wherein the first control signal and the symmetric and antisymmetric composite portions of the second control signal are activated during a same time period.

14. The method of claim 12, wherein the operation of providing the first control signal comprises:
providing a first sin^{m} pulse;
providing a square pulse after providing the first sin^{m} pulse; and
providing a second sin^{m} pulse providing the square pulse.

15. The method of claim 14, wherein the operation of modifying the first and second control signals comprises modifying a parameter corresponding to a maximum value of the first and second sin^{m} pulses and the square pulse.

16. The method of claim 12, wherein the second control signal further comprises first and second amplitude portions,
wherein the first amplitude portion comprises first and second composite portions, and the second amplitude portion comprises third and fourth composite portions,
wherein each of the first composite portion, the second composite portion, the third composite portion, and the fourth composite portion comprises a combination of sinⁿ waves, and n is an odd integer.

17. A method, comprising:
loading, in response to a plurality of voltage signals applied on a plurality of gate structures in a quantum device, a first electron and a second electron from a reservoir region into a first quantum dot and a second quantum dot that are in the quantum device, wherein the first and second quantum dots are underneath first and second gate structures in the plurality of gate structures, and the reservoir region is underneath a third gate structure in the plurality of gate structures; and
performing a first quantum gate operation to modulate a spin of the first electron, a spin of the second electron, or a combination thereof by simultaneously applying a coupling signal and a magnetic field to the first and second quantum dots, wherein the coupling signal comprises a first sine squared wave and is generated in response to a first voltage signal, in the plurality of voltage signals, applied on a fourth gate structure, in the plurality of gate structures, interposed between the first and second gate structures.

18. The method of claim 17, wherein
the coupling signal is a combination of the first sine squared wave and at least one second sine squared wave, and the magnetic field comprises a combination of sinⁿ waves, and n is an odd integer;
wherein the first quantum gate operation is a controlled-NOT (CNOT) quantum gate operation.

19. The method of claim 17, wherein
the coupling signal further comprises a second sine squared wave,
wherein the first and second sine squared waves are activated in a sequential order and have a same maximum value, and the first quantum gate operation is a controlled-Z (CZ) quantum gate operation.

20. The method of claim 19, further comprising:
performing a second quantum gate operation on the spin of one of the first and second electrons before performing the first quantum gate operation for performing a third quantum gate operation to the spin of the first electron, the spin of the second electron, or the combination thereof.
